(19) United States
(12) Patent Application Publication
(10) Pub. No.: US 2026/0358170 A1
(43) Pub. Date: Nov. 12, 2026

(54) LIGHT DETECTING DEVICE AND ELECTRONIC APPARATUS

(71) Applicant: SONY SEMICONDUCTOR SOLUTIONS CORPORATION, KANAGAWA (JP)

(72) Inventor: KOJI MIYATA, KANAGAWA (JP)

(21) Appl. No.: 19/486,054

(22) PCT Filed: May 17, 2024
(86) PCT No.: PCT/JP2024/018339

§ 371 Date: Nov. 20, 2025

(30) Foreign Application Priority Data
Jun. 7, 2023 (JP) 2023-094208

(51) Int. Cl. G01J 1/04; G01J 1/44; G02B 5/20

(52) U.S. Cl. CPC G01J 1/0492; G01J 1/44; G02B 5/201

(57) ABSTRACT

A light detecting device according to an embodiment of the present disclosure includes: a first pixel and a second pixel each including a first photoelectric conversion element that photoelectrically converts light; a first filter provided in a manner corresponding to the first pixel; a second filter provided in a manner corresponding to the second pixel; a first light-guiding member provided between the first filter and the second filter; and a second light-guiding member provided around the first light-guiding member and having a refractive index higher than a refractive index of the first light-guiding member.

### TECHNICAL FIELD

The present disclosure relates to a light detecting device and an electronic apparatus.

### BACKGROUND ART

An imaging device has been proposed that includes a light-blocking film formed at a boundary part between adjacent pixels, and a first low refractive index film and a second low refractive index film formed on the light-blocking film (PTL 1).

### CITATION LIST

### Patent Literature

PTL 1: International Publication No. WO2017/073321 SUMMARY OF THE INVENTION

It is desired, for a device that detects light, to improve detection performance.

It is desirable to provide a light detecting device having favorable detection performance.

A light detecting device according to an embodiment of the present disclosure includes: a first pixel and a second pixel each including a first photoelectric conversion element that photoelectrically converts light; a first filter provided in a manner corresponding to the first pixel; a second filter provided in a manner corresponding to the second pixel; a first light-guiding member provided between the first filter and the second filter; and a second light-guiding member provided around the first light-guiding member and having a refractive index higher than a refractive index of the first light-guiding member.

An electronic apparatus according to an embodiment of the present disclosure includes: an optical system; and a light detecting device that receives light transmitted through the optical system. The light detecting device includes a first pixel and a second pixel each including a first photoelectric conversion element that photoelectrically converts light, a first filter provided in a manner corresponding to the first pixel, a second filter provided in a manner corresponding to the second pixel, a first light-guiding member provided between the first filter and the second filter, and a second light-guiding member provided around the first light-guiding member and having a refractive index higher than a refractive index of the first light-guiding member.

### BRIEF DESCRIPTION OF THE DRAWINGS

FIG. 1 is a block diagram illustrating an example of a schematic configuration of an imaging device which is an example of a light detecting device according to an embodiment of the present disclosure.

FIG. 2 is a diagram illustrating an example of a pixel section of the imaging device according to an embodiment of the present disclosure.

FIG. 3 is a diagram illustrating an example of a planar configuration of the imaging device according to an embodiment of the present disclosure.

FIG. 4 is a diagram illustrating an example of a cross-sectional configuration of the imaging device according to an embodiment of the present disclosure.

FIG. 5 is an explanatory diagram of a configuration example of the imaging device according to an embodiment of the present disclosure.

FIG. 6 is a diagram illustrating an example of the cross-sectional configuration of the imaging device according to an embodiment of the present disclosure.

FIG. 7 is a diagram illustrating an example of the cross-sectional configuration of the imaging device according to an embodiment of the present disclosure.

FIG. 8 is an explanatory diagram of an example of a cross-sectional configuration of the imaging device according to an embodiment of the present disclosure.

FIG. 9 is an explanatory diagram of another example of the cross-sectional configuration of the imaging device according to an embodiment of the present disclosure.

FIG. 10 is an explanatory diagram of another example of the cross-sectional configuration of the imaging device according to an embodiment of the present disclosure.

FIG. 11A is an explanatory diagram of an example of a planar configuration of the imaging device according to an embodiment of the present disclosure.

FIG. 11B is an explanatory diagram of an example of the planar configuration of the imaging device according to an embodiment of the present disclosure.

FIG. 11C is an explanatory diagram of an example of the planar configuration of the imaging device according to an embodiment of the present disclosure.

FIG. 12 is an explanatory diagram of a configuration example of an imaging device according to Modification Example 1 of the present disclosure.

FIG. 13 is an explanatory diagram of another configuration example of the imaging device according to Modification Example 1 of the present disclosure.

FIG. 14 is an explanatory diagram of another configuration example of the imaging device according to Modification Example 1 of the present disclosure.

FIG. 15 is an explanatory diagram of another configuration example of the imaging device according to Modification Example 1 of the present disclosure.

FIG. 16A is an explanatory diagram of a configuration example of pixels at positions of different image heights of an imaging device according to Modification Example 2 of the present disclosure.

FIG. 16B is an explanatory diagram of a configuration example of pixels at positions of different image heights of the imaging device according to Modification Example 2 of the present disclosure.

FIG. 16C is an explanatory diagram of a configuration example of pixels at positions of different image heights of the imaging device according to Modification Example 2 of the present disclosure.

FIG. 17A is an explanatory diagram of another configuration example of the pixels at positions of different image heights of the imaging device according to Modification Example 2 of the present disclosure.

FIG. 17B is an explanatory diagram of another configuration example of the pixels at positions of different image heights of the imaging device according to Modification Example 2 of the present disclosure.

FIG. 17C is an explanatory diagram of another configuration example of the pixels at positions of different image heights of the imaging device according to Modification Example 2 of the present disclosure.

FIG. 18 is an explanatory diagram of a configuration example of an imaging device according to Modification Example 3 of the present disclosure.

FIG. 19 is an explanatory diagram of another configuration example of the imaging device according to Modification Example 3 of the present disclosure.

FIG. 20 is an explanatory diagram of another configuration example of the imaging device according to Modification Example 3 of the present disclosure.

FIG. 21 is an explanatory diagram of another configuration example of the imaging device according to Modification Example 3 of the present disclosure.

FIG. 22A is an explanatory diagram of a configuration example of an imaging device according to Modification Example 4 of the present disclosure.

FIG. 22B is an explanatory diagram of a configuration example of the imaging device according to Modification Example 4 of the present disclosure.

FIG. 23A is an explanatory diagram of another configuration example of the imaging device according to Modification Example 4 of the present disclosure.

FIG. 23B is an explanatory diagram of another configuration example of the imaging device according to Modification Example 4 of the present disclosure.

FIG. 24A is an explanatory diagram of another configuration example of the imaging device according to Modification Example 4 of the present disclosure.

FIG. 24B is an explanatory diagram of another configuration example of the imaging device according to Modification Example 4 of the present disclosure.

FIG. 25 is an explanatory diagram of an example of a planar configuration of an imaging device according to Modification Example 5 of the present disclosure.

FIG. 26 is an explanatory diagram of an example of a cross-sectional configuration of the imaging device according to Modification Example 5 of the present disclosure.

FIG. 27 is an explanatory diagram of an example of a cross-sectional configuration of the imaging device according to Modification Example 5 of the present disclosure.

FIG. 28 is a block diagram illustrating a configuration example of an electronic apparatus including the imaging device.

FIG. 29 is a block diagram depicting an example of schematic configuration of a vehicle control system.

FIG. 30 is a diagram of assistance in explaining an example of installation positions of an outside-vehicle information detecting section and an imaging section.

FIG. 31 is a view depicting an example of a schematic configuration of an endoscopic surgery system.

FIG. 32 is a block diagram depicting an example of a functional configuration of a camera head and a camera control unit (CCU).

### MODES FOR CARRYING OUT THE INVENTION

Hereinafter, a description is given in detail of embodiments of the present disclosure with reference to the drawings. It is to be noted that the description is given in the following order.
1. Embodiment
2. Modification Examples
3. Application Example
4. Practical Application Examples

### 1. Embodiment

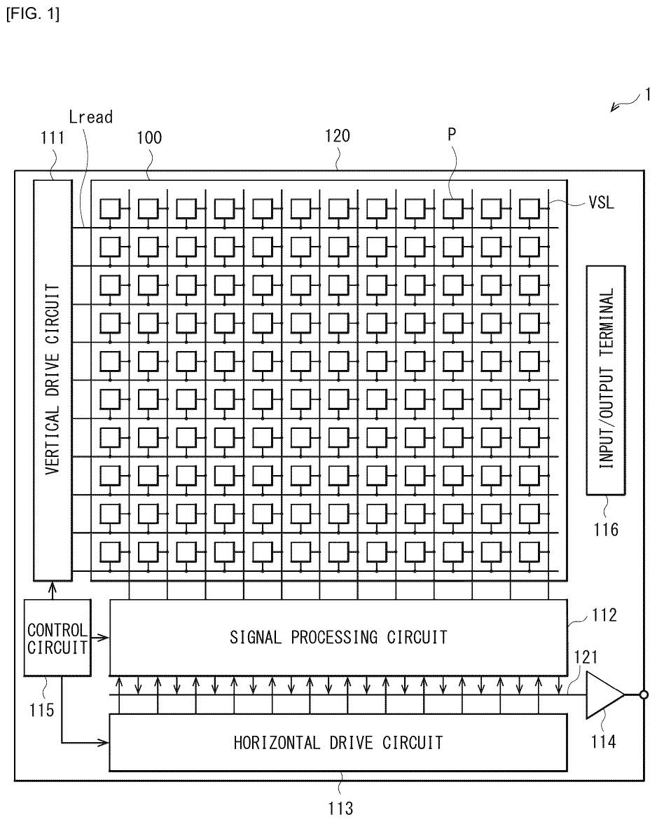

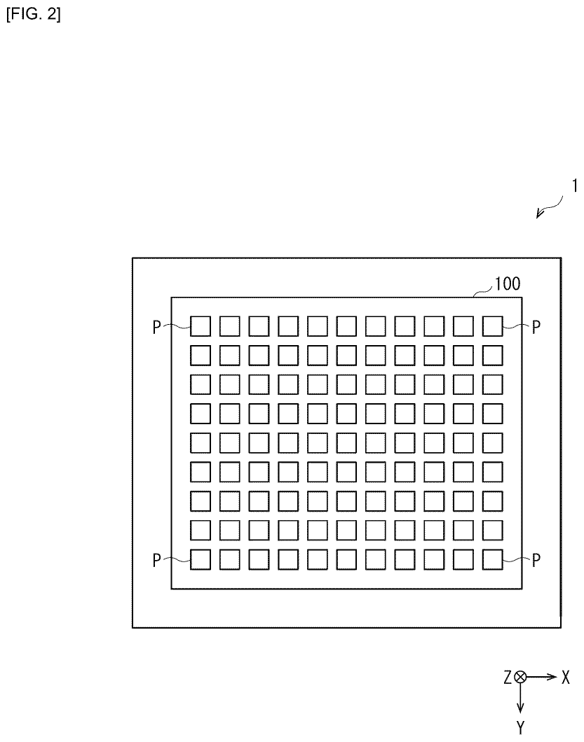

FIG. 1 is a block diagram illustrating an example of a schematic configuration of an imaging device which is an example of a light detecting device according to an embodiment of the present disclosure. FIG. 2 is a diagram illustrating an example of a pixel section of the imaging device according to the embodiment. The light detecting device is a device that is able to detect incident light. An imaging device 1, which is a light detecting device, is able to, for example, receive light transmitted through an optical system and generate a signal. The imaging device 1 (light detecting device) includes a plurality of pixels P each including a photoelectric conversion section (photoelectric conversion element), and is configured to photoelectrically convert incident light and generate a signal.

The photoelectric conversion section of each of the pixels P is, for example, a photodiode, and is configured to be able to photoelectrically convert light. As in the example illustrated in FIGS. 1 and 2, the imaging device 1 includes, as an imaging area, a region (a pixel section 100) in which the plurality of pixels P is two-dimensionally arranged in matrix. The pixel section 100 is a pixel array in which the plurality of pixel P is arranged, and may also be referred to as a light-receiving section (light-receiving region). The photoelectric conversion section of each of the pixels P may also be referred to as a photoelectric conversion region.

The imaging device 1 takes in incident light (image light) from a subject via an optical system (unillustrated) including an optical lens. The imaging device 1 may capture an image of the subject formed by the optical lens. The imaging device 1 photoelectrically converts received light to generate a pixel signal. The imaging device 1 is, for example, a CMOS (Complementary Metal Oxide Semiconductor) image sensor. The imaging device 1 is usable for an electronic apparatus such as a digital still camera, a video camera, or a mobile phone.

It is to be noted that, as illustrated in FIG. 2, a direction in which light from the subject is incident is defined as a Z-axis direction; a right-left direction on the sheet orthogonal to the Z-axis direction is defined as an X-axis direction; and an up-down direction on the sheet orthogonal to the Z-axis direction and the X-axis direction is defined as a Y-axis direction. In the following drawings, the arrow directions in FIG. 2 may be used, in some cases, as a standard to express a direction.

As in the example illustrated in FIG. 1, the imaging device 1 includes, in a peripheral region of the pixel section 100 (pixel array), for example, a vertical drive circuit 111, a signal processing circuit 112, a horizontal drive circuit 113, an output circuit 114, a control circuit 115, and an input/output terminal 116. In addition, the imaging device 1 is provided with a plurality of pixel drive lines Lread and a plurality of vertical signal lines VSL.

In the pixel section 100, in the example illustrated in FIG. 1, the plurality of pixel drive lines Lread is wired for respective pixel rows each configured by the plurality of pixels P arranged in a horizontal direction (row direction). The pixel drive line Lread is a signal line that is able to transmit a signal to drive the pixel P. The pixel drive line Lread is configured to transmit a drive signal to read a signal from the pixel P.

In addition, in the pixel section 100, the vertical signal lines VSL are wired for respective pixel columns each configured by the plurality of pixels P arranged in a vertical direction (column direction). The vertical signal line VSL is a signal line that is able to transmit a signal from the pixel P. The vertical signal line VSL is configured to transmit a signal outputted from the pixel P.

The vertical drive circuit 111 is configured by, for example, a buffer, a shift register, an address decoder, and the like. The vertical drive circuit 111 is configured to be able to drive each of the pixels P of the pixel section 100. The vertical drive circuit 111 generates a signal to drive the pixel P, and outputs the signal to each of the pixels P of the pixel section 100 via the pixel drive line Lread. The vertical drive circuit 111 generates, for example, a signal to control a selection transistor, a signal to control a reset transistor, or the like, and supplies the signal to each of the pixels P by the pixel drive line Lread.

The signal processing circuit 112 is configured to be able to execute signal processing of an inputted pixel signal. The signal processing circuit 112 includes, for example, a load circuit, an AD (Analog-to-Digital) conversion circuit, a horizontal selection switch, and the like. As an example, the load circuit is configured by a current source that is able to supply a current to an amplification transistor of the pixel P. The load circuit constitutes a source follower circuit together with the amplification transistor of the pixel P, for example.

The signal processing circuit 112 may include an amplification circuit configured to amplify a signal read from the pixel P via the vertical signal line VSL. For example, the load circuit, the amplification circuit, the AD conversion circuit, and the like are provided for each of the plurality of vertical signal lines VSL. The load circuit, the AD conversion circuit, and the like may be provided for each of the pixel columns of the pixel section 100.

The signal outputted from each of the pixels P selected and scanned by the vertical drive circuit 111 is inputted to the signal processing circuit 112 via the vertical signal line VSL. The signal processing circuit 112 performs signal processing such as CDS (Correlated Double Sampling: correlated double sampling) and AD conversion of the signal of the pixel P.

The horizontal drive circuit 113 is configured by, for example, a buffer, a shift register, an address decoder, and the like. The horizontal drive circuit 113 is configured to be able to drive the horizontal selection switch of the signal processing circuit 112. The horizontal drive circuit 113 sequentially drives horizontal selection switches of the signal processing circuit 112 while scanning. Signals of the respective pixels P transmitted through the respective vertical signal lines VSL are subjected to signal processing by the signal processing circuit 112, and are sequentially outputted to a horizontal signal line 121 by selective scanning by the horizontal drive circuit 113.

The output circuit 114 is configured to perform signal processing on an inputted signal to output a signal. The output circuit 114 performs signal processing on the pixel signal inputted sequentially from the signal processing circuit 112 via the horizontal signal line 121, and outputs the processed pixel signal. The output circuit 114 may perform, for example, buffering, black level adjustment, column variation correction, various types of digital signal processing, and the like.

The control circuit 115 is configured to be able to control each section of the imaging device 1. The control circuit 115 may receive a clock supplied from the outside of a semiconductor substrate 120, data ordering an operation mode, or the like, and output data such as internal information on the imaging device 1. The control circuit 115 includes, for example, a timing generator configured to be able to generate various timing signals.

The control circuit 115 controls driving of peripheral circuits such as the vertical drive circuit 111, the signal processing circuit 112, and the horizontal drive circuit 113 on the basis of the various timing signals (pulse signal, clock signal, etc.) generated by the timing generator. The input/output terminal 116 exchanges signals with the outside.

It is to be noted that the vertical drive circuit 111, the signal processing circuit 112, the horizontal drive circuit 113, the horizontal signal line 121, the output circuit 114, the control circuit 115, and the like may be provided in the semiconductor substrate 120, or may be provided in another substrate. The imaging device 1 may have a structure (stacked structure) configured by stacking a plurality of substrates.

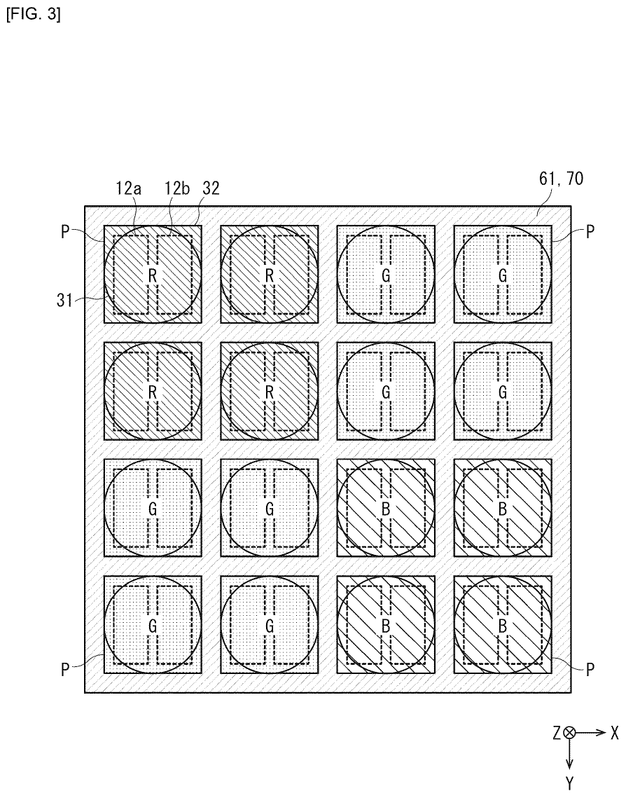

FIG. 3 is a diagram illustrating an example of a planar configuration of the imaging device according to the embodiment. FIG. 3 illustrates an arrangement example of the pixels P of the pixel section 100 of the imaging device 1. The pixel P of the imaging device 1 includes a plurality of photoelectric conversion sections 12 (a first photoelectric conversion section 12a and a second photoelectric conversion section 12b in the example illustrated in FIG. 3), a lens 31, and a filter 32.

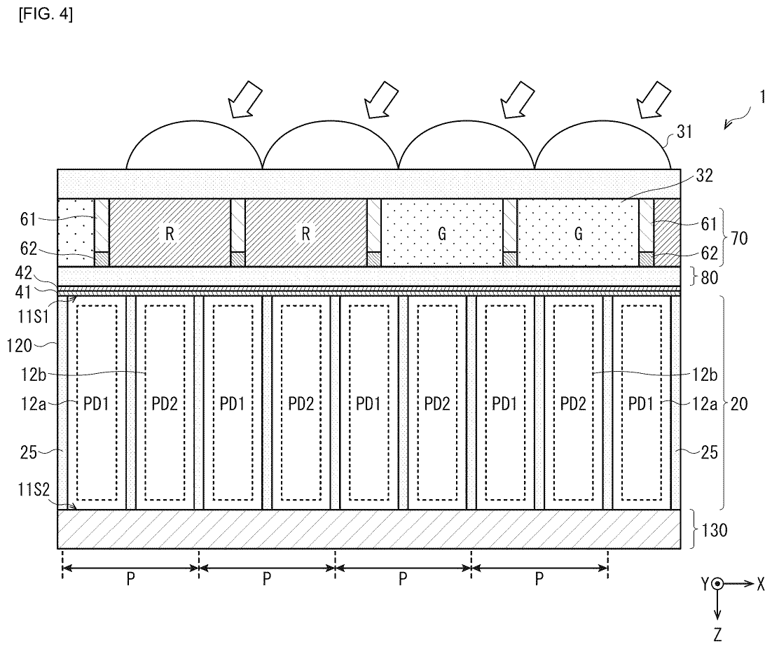

The second photoelectric conversion section 12b is provided next to the first photoelectric conversion section 12a. It can also be said that there are provided a pixel including the first photoelectric conversion section 12a and a pixel including the second photoelectric conversion section 12b. In addition, the pixel P includes a light-guiding wall 70 including a first light-guiding member 61 and a second light-guiding member 62 (see FIG. 4 and other drawings), as described later. It is to be noted that the pixel P may include three or more photoelectric conversion sections 12. The pixel P may include, for example, four photoelectric conversion sections 12.

The lens 31 guides incident light to a side of the photoelectric conversion section 12 of the pixel P. The lens 31 is a lens that condenses light, and is an optical member also called an on-chip lens. The lens 31 is provided, for example, for each of the pixels P or for every plurality of pixels P. Light from a subject which is a measurement target is incident on the lens 31 via the optical system such as an imaging lens. The lens 31 and the filter 32 may be provided on a side on which light from the optical system is incident. The photoelectric conversion section 12 of the pixel P photoelectrically converts light incident via the lens 31 and the filter 32.

The filter 32 is configured to selectively transmit light of a particular wavelength region of the incident light. The filter 32 is, for example, a color filter of RGB. The filter 32 is provided above the photoelectric conversion section 12 for each of the pixels P or for every plurality of pixels P, for example.

The plurality of pixels P provided in the pixel section 100 of the imaging device 1 includes a plurality of pixels (R pixels) provided with the filter 32 that transmits red (R) light, a plurality of pixels (G pixels) provided with the filter 32 that transmits green (G) light, and a plurality of pixels (B pixels) provided with the filter 32 that transmits blue (B) light.

In the pixel section 100, the plurality of R pixels, the plurality of G pixels, and the plurality of B pixels are repeatedly arranged. As an example, the R pixel, the G pixel, and the B pixel are arranged in accordance with a Bayer arrangement. The R pixel, the G pixel, and the B pixel may each be arranged in a unit of 2×2 pixels.

For example, in the pixel section 100, four adjacent R pixels, four adjacent G pixels, and four adjacent B pixels are repeatedly arranged. It can also be said that the R pixels, the G pixels, and the B pixels are each arranged cyclically in two rows by two columns.

The R pixel, the G pixel, and the B pixel generate an R-component pixel signal, a G-component pixel signal, and a B-component pixel signal, respectively. The imaging device 1 is able to obtain pixel signals of RGB. It is to be noted that the arrangement of the pixels P is not limited to the above-described example, and may be set optionally.

The filter 32 provided for the pixels P of the pixel section 100 is not limited a color filter of a primary color system (RGB), and may be, for example, a color filter of a complementary color system such as Cy (cyan), Mg (magenta), and Ye (yellow). A filter corresponding to W (white), i.e., a filter that transmits light beams of all wavelength regions of incident light may be arranged. The filter 32 may be a filter that transmits infrared light.

It is to be noted that, in the imaging device 1, the filter 32 may be omitted as needed. The filter 32 may not be provided in some of the pixels of the imaging device 1. For example, the filter 32 may not be provided in a pixel that receives white (W) light to perform photoelectric conversion.

FIG. 4 is a diagram illustrating an example of a cross-sectional configuration of an imaging device according to the embodiment. For example, as illustrated in FIG. 4, the imaging device 1 includes the lens 31, the filter 32, an insulating layer 80, a light-receiving section 20, and a multilayer wiring layer 130. It is to be noted that FIG. 4 illustrates an example of a cross-sectional configuration in a region where a distance from the center of the pixel section 100 (light-receiving section 20), i.e., an image height is high.

The imaging device 1 has a configuration in which the lens 31, the filter 32, the insulating layer 80, the light-receiving section 20, and the multilayer wiring layer 130 are stacked in the Z-axis direction. The lens 31, the filter 32, the insulating layer 80, the light-receiving section 20, and the multilayer wiring layer 130 are provided from the side on which light is incident.

As illustrated in FIG. 4, the light-receiving section 20 (light-receiving layer) includes the semiconductor substrate 120 having a first surface 11S1 and a second surface 11S2 opposed to each other. The second surface 11S2 is a surface on a side opposite to the first surface 11S1. The first surface 11S1 of the semiconductor substrate 120 is a light-receiving surface (light incident surface). The second surface 11S2 of the semiconductor substrate 120 is an element formation surface on which an element such as a transistor is formed. The second surface 11S2 of the semiconductor substrate 120 is provided with a gate electrode, a gate insulating film (e.g., a gated oxide film), and the like.

The semiconductor substrate 120 is configured by an Si (silicon) substrate, for example. The semiconductor substrate 120 may also be referred to as a semiconductor layer. The semiconductor substrate 120 may be an SOI (Silicon On Insulator) substrate, an SiGe (silicon germanium) substrate, an SiC (silicon carbide) substrate, or the like, and may be formed using another semiconductor material.

In the example illustrated in FIG. 4, the insulating layer 80, the filter 32, and the like are provided on a side of the first surface 11S1 of the semiconductor substrate 120 (semiconductor layer). The lens 31 and the filter 32 are stacked over the light-receiving section 20 in a thickness direction orthogonal to the first surface 11S1 of the semiconductor substrate 120. The photoelectric conversion section 12 (the first photoelectric conversion section 12a and the second photoelectric conversion section 12b in FIG. 4) photoelectrically converts light incident via the lens 31 and the filter 32.

The multilayer wiring layer 130 is provided on a side of the second surface 11S2 of the semiconductor substrate 120. The filter 32, the insulating layer 80, and the like are provided on the side on which light from the optical system is incident, and the multilayer wiring layer 130 is provided on a side opposite to the side on which light is incident. The imaging device 1 is a so-called back side illumination imaging device.

The pixel P of the imaging device 1 includes the first photoelectric conversion section 12a, the second photoelectric conversion section 12b, and a readout circuit (unillustrated). The first photoelectric conversion section 12a and the second photoelectric conversion section 12b are each configured to receive light and generate a signal (signal charge). The readout circuit includes, for example, a plurality of transistors, and is configured to be able to output a signal based on photoelectrically converted electric charge.

The first photoelectric conversion section 12a (first photoelectric conversion element) is configured to be able to generate electric charge by photoelectric conversion. The first photoelectric conversion section 12a is a first photodiode (PD1), and may photoelectrically convert incident light to generate electric charge corresponding to a received light amount. The first photoelectric conversion section 12a may also be referred to as a first photoelectric conversion layer.

The second photoelectric conversion section 12b (second photoelectric conversion element) is configured to be able to generate electric charge by photoelectric conversion. The second photoelectric conversion section 12b is a second photodiode (PD2), and may photoelectrically convert incident light to generate electric charge corresponding to a received light amount. The second photoelectric conversion section 12b may also be referred to as a second photoelectric conversion layer.

In the light-receiving section 20, a plurality of first photoelectric conversion sections 12a and a plurality of second photoelectric conversion sections 12b are provided along the first surface 11S1 and the second surface 11S2 of the semiconductor substrate 120. For example, the plurality of first photoelectric conversion sections 12a and the plurality of second photoelectric conversion sections 12b are formed to be embedded in the semiconductor substrate 120. The first photoelectric conversion section 12a and the second photoelectric conversion section 12b are provided between the first surface 11S1 and the second surface 11S2 of the semiconductor substrate 120.

The readout circuit of the pixel P is configured to be able to output a signal (first pixel signal) based on electric charge generated by the first photoelectric conversion section 12a and a signal (second pixel signal) based on electric charge generated by the second photoelectric conversion section 12b. The readout circuit includes, for example, a transfer transistor, a floating diffusion (FD), an amplification transistor, a selection transistor, a reset transistor, and the like.

The transistors such as the transfer transistor, the amplification transistor, the selection transistor, and the reset transistor of the readout circuit are each configured by, for example, a MOS transistor (MOSFET). The readout circuit is configured to be able to read the first pixel signal and the second pixel signal to the vertical signal line VSL (see FIG. 1).

The vertical drive circuit 111 (see FIG. 1) supplies a control signal to gates of the transfer transistor, the selection transistor, the reset transistor, and the like of each of the pixels P via the pixel drive line Lread described above to bring the transistors into an ON state (electrically-conductive state) or into an OFF state (non-electrically-conductive state). The plurality of pixel drive lines Lread of the imaging device 1 includes, for example, wiring that transmits a signal to control the transfer transistor, wiring that transmits a signal to control the selection transistor, and wiring that transmits a signal to control the reset transistor.

The transfer transistor, the selection transistor, the reset transistor, and the like are controlled ON/OFF by the vertical drive circuit 111. The vertical drive circuit 111 controls the readout circuit of each of the pixels P to thereby cause each of the pixels P to output a pixel signal to the vertical signal line VSL. The vertical drive circuit 111 may perform control to read the pixel signal of each of the pixels P to the vertical signal line VSL.

The vertical drive circuit 111 is able to read the first pixel signal based on electric charge photoelectrically converted by the first photoelectric conversion section 12a and the second pixel signal based on electric charge photoelectrically converted by the second photoelectric conversion section 12b. In addition, the vertical drive circuit 111 may read a pixel signal corresponding to electric charge obtained by adding electric charge converted by the first photoelectric conversion section 12a and electric charge converted by the second photoelectric conversion section 12b.

The multilayer wiring layer 130 is stacked on the semiconductor substrate 120. The multilayer wiring layer 130 includes, for example, a conductive film and an insulating film, and includes a plurality of wirings, vias (VIA), and the like. The multilayer wiring layer 130 has a configuration in which a plurality of wirings is stacked, with an insulating film as an interlayer insulating film (interlayer insulating layer) being interposed therebetween.

The wiring of the multilayer wiring layer 130 is formed using a metal material such as aluminum (Al), tungsten (W), or copper (Cu), for example. The wiring of the multilayer wiring layer 130 may be configured using polysilicon (Poly-Si), or another electrically-conductive material. The interlayer insulating film is formed using silicon oxide (SiO), silicon nitride (SiN), silicon oxynitride (SiON), or the like, for example.

The above-described readout circuit is provided in the semiconductor substrate 120 and the multilayer wiring layer 130 for each of the pixels P or for every plurality of pixels P, for example. In addition, the vertical drive circuit 111, the signal processing circuit 112, the horizontal drive circuit 113, the output circuit 114, the control circuit 115, and the like described above (see FIG. 1) may be provided in the semiconductor substrate 120 and the multilayer wiring layer 130, or in a substrate different from the semiconductor substrate 120. It is to be noted that the semiconductor substrate 120 and a portion or all of the multilayer wiring layer 130 may also be collectively referred to as the semiconductor substrate 120.

In the present embodiment, one lens 31 (lens section) is provided for the plurality of photoelectric conversion sections 12, e.g., the two photoelectric conversion sections 12 (the first photoelectric conversion section 12a and the second photoelectric conversion section 12b). In the imaging device 1, the first photoelectric conversion section 12a and the second photoelectric conversion section 12b receive light having passed through different regions of the optical system such as the imaging lens to allow pupil division to be performed.

Using the first pixel signal based on electric charge converted by the first photoelectric conversion section 12a and the second pixel signal based on electric charge converted by the second photoelectric conversion section 12b enables phase difference data (phase difference information) to be obtained. Using the phase difference data enables phase difference AF (Auto Focus) to be performed.

The pixel P of the imaging device 1 is a pixel usable for detection of a phase difference, and may also be referred to as a phase difference pixel (or a phase difference detection pixel). As described above, the pixel P is configured to be able to output the first pixel signal and the second pixel signal, as signals to be used for detection of a phase difference. In addition, in the present embodiment, the pixels P, which are the phase difference pixels, may be repeatedly provided across the entire surface of an imaging plane of the imaging device 1, i.e., across the entire pixel section 100. It is possible to obtain phase difference data across the entire surface of the imaging plane of the imaging device 1, and thus to perform high-precision AF (auto-focus).

In addition, it is possible to perform signal processing on pixel signals outputted from respective pixels of the R pixel, the G pixel, and the B pixel of the pixel section 100, and thus to generate image data. The image data may be generated using pixel signals based on electric charge obtained by adding the electric charge converted by the first photoelectric conversion section 12a and the electric charge converted by the second photoelectric conversion section 12b. It is possible, in the imaging device 1, to obtain a pixel signal for image generation across the entire surface of the imaging plane. This makes it possible to suppress deterioration in image quality of an image.

The insulating layer 80 is provided between the layer provided with the light-receiving section 20 and the layer provided with the filter 32. In the example illustrated in FIG. 4, the insulating layer 80 is stacked over the light-receiving section 20 (light-receiving layer), and is positioned over the first surface 11S1 of the semiconductor substrate 120. As an example, the insulating layer 80 is configured using an insulating film such as an oxide film, a nitride film, or an oxynitride film.

The insulating layer 80 may be formed using, for example, an insulating material such as silicon oxide (SiO), silicon nitride (SiN), or aluminum oxide (AlO). The insulating layer 80 may be configured by a low refractive index material such as silicon oxide, or may be configured by another material that transmits light of a wavelength region to be a detection target. It is to be noted that the insulating layer 80 may also be referred to as a planarization layer (planarization film).

In addition, as illustrated in FIG. 4, the imaging device 1 is provided with a separation section 25, a fixed charge film 41, an antireflection film 42, and the light-guiding wall 70. The separation section 25 is formed between the plurality of photoelectric conversion sections 12 adjacent to each other to separate the photoelectric conversion sections 12 from each other. The separation section 25 is configured using, for example, a trench (groove part) provided at a boundary between the plurality of pixels P (or the photoelectric conversion sections 12) adjacent to each other.

In the example illustrated in FIG. 4, the separation section 25 is provided between the first photoelectric conversion section 12a and the second photoelectric conversion section 12b. The separation section 25 may be formed to surround each of the first photoelectric conversion section 12a and the second photoelectric conversion section 12b in the semiconductor substrate 120. The separation section 25 may be provided to penetrate the semiconductor substrate 120, for example, as in the example illustrated in FIG. 4.

As an example, in the trench of the separation section 25, there is provided an insulating film, e.g., a silicon oxide film, an aluminum oxide film, or the like. The separation section 25 may be formed using another insulating material having a low refractive index. An air gap (cavity) may be provided in the trench of the separation section 25.

It is to be noted that polysilicon, a metal material, another insulating material, or the like may be embedded in the trench of the separation section 25. The separation section 25 may be configured by a semiconductor region (a p-type or an n-type semiconductor region) formed by ion implantation. It is to be noted that the separation section 25 may also be referred to as a pixel separation section or a pixel separation wall.

In the imaging device 1, providing the separation section 25 suppresses leakage, to surrounding pixels P, of electric charge photoelectrically converted by the first photoelectric conversion section 12a or the second photoelectric conversion section 12b of the pixel P. In addition, it is possible, in the imaging device 1, to suppress leakage of light to the surrounding pixels P.

As in the example illustrated in FIG. 4, the imaging device 1 may include the fixed charge film 41 and the antireflection film 42. As an example, the fixed charge film 41 and the antireflection film 42 are each configured by a metal compound (metal oxide, metal nitride, etc.), and may each also be referred to as a metal compound layer. The fixed charge film 41 and the antireflection film 42 are provided on the side of the first surface 11S1 of the semiconductor substrate 120.

The fixed charge film 41 is provided between the semiconductor substrate 120 and the insulating layer 80, for example. The fixed charge film 41 is provided for the first photoelectric conversion section 12a and the second photoelectric conversion section 12b of each of the pixels P, and is positioned on the first photoelectric conversion section 12a and the second photoelectric conversion section 12b. In the example illustrated in FIG. 4, the fixed charge film 41 is provided to cover the first photoelectric conversion section 12a and the second photoelectric conversion section 12b.

The fixed charge film 41 is a film having fixed electric charge, and may be formed using a high dielectric material. As an example, the fixed charge film 41 is configured by a metal oxide such as hafnium oxide or aluminum oxide. The fixed charge film 41 is, for example, a film having negative fixed electric charge. The fixed charge film 41 may be formed using a metal nitride film or a metal oxynitride film. Providing the fixed charge film 41 suppresses generation of a dark current at an interface with the semiconductor substrate 120. It is to be noted that a film having positive fixed electric charge may be provided as the fixed charge film 41.

As an example, the antireflection film 42 is configured by a metal oxide such as hafnium oxide or tantalum oxide, and is provided on the fixed charge film 41. The antireflection film 42 may be configured by another metal oxide film, or may be configured by a metal nitride film or a metal oxynitride film. The antireflection film 42 is provided between the fixed charge film 41 and the insulating layer 80, and reduces (suppresses) reflection.

The antireflection film 42 may be configured using an insulating material such as silicon oxide, silicon nitride, or silicon oxynitride, or may be configured using another material. It is to be noted that the insulating layer 80 may include at least one of the fixed charge film 41 or the antireflection film 42. The imaging device 1 may include only one of the fixed charge film 41 or the antireflection film 42.

The light-guiding wall 70 is provided between a plurality of filters 32 adjacent to each other, for example, as in the example illustrated in FIG. 4. The light-guiding wall 70 includes the first light-guiding member 61 and the second light-guiding member 62, and is configured to guide incident light to the side of the photoelectric conversion section 12. The light-guiding wall 70 is a wall-shaped structure, and is provided around the filter 32. At least a portion of the light-guiding wall 70 is provided at a boundary between the plurality of pixels P adjacent to each other, and may also be referred to as a separation wall (or separation section) that separates the filters 32 from each other.

The first light-guiding member 61 is formed between the plurality of filters 32 adjacent to each other. The first light-guiding member 61 is provided to surround the filter 32 in a plan view, for example, as in the example illustrated in FIG. 3. The first light-guiding member 61 has a refractive index lower than a refractive index of a surrounding medium. In the example illustrated in FIG. 4, the first light-guiding member 61 is positioned at a side surface (side part) of the filter 32, and has a refractive index lower than a refractive index of the filter 32.

The first light-guiding member 61 is configured by an air gap (cavity), silicon oxide, or the like. The first light-guiding member 61 may be configured using, for example, an air gap (air gap). The first light-guiding member 61 has an air gap (air) provided between the plurality of filters 32 adjacent to each other, and may also be referred to as a light-guiding member that utilizes air (air layer).

The first light-guiding member 61 may be configured using another dielectric material having a low refractive index. The first light-guiding member 61 may be formed using an organic material. The first light-guiding member 61 changes a traveling direction of incident light in accordance with a difference in refractive indexes between the first light-guiding member 61 and a medium therearound.

In the imaging device 1, a propagation direction of light incident on the first light-guiding member 61 is adjusted, thus enabling the light to be guided to the side of the photoelectric conversion section 12. Providing the light-guiding wall 70 suppresses leakage of light to surrounding pixels P, thus reducing color mixture (crosstalk).

The second light-guiding member 62 is provided around the first light-guiding member 61. The second light-guiding member 62 is provided above the photoelectric conversion section 12, and is positioned below the first light-guiding member 61, for example. In the example illustrated in FIG. 4, the second light-guiding member 62 is provided with respect to the bottom of the first light-guiding member 61, and is in contact with the first light-guiding member 61. The first light-guiding member 61 and the second light-guiding member 62 may be formed to be stacked on each other.

The second light-guiding member 62 has a refractive index higher than a refractive index of a surrounding medium. The second light-guiding member 62 is provided, for example, to be in contact with the first light-guiding member 61, and has a refractive index higher than a refractive index of the first light-guiding member 61. In the example illustrated in FIG. 4, the second light-guiding member 62 is positioned at the side surface of the filter 32, on the insulating layer 80. The second light-guiding member 62 may have a refractive index higher than the refractive index of the filter 32.

The second light-guiding member 62 is configured by a material having a refractive index higher than the refractive index of the first light-guiding member 61. The second light-guiding member 62 is configured by, for example, a metal oxide such as titanium oxide (TiO) or tantalum oxide (TaO). It can also be said that the first light-guiding member 61 is a low refractive index section and the second light-guiding member 62 is a high refractive index section. As an example, the first light-guiding member 61 and the second light-guiding member 62 may each be disposed between the filters 32 adjacent to each other, and may be positioned at a boundary between the filters 32 adjacent to each other.

The second light-guiding member 62 may be formed to include at least one of oxides of elements such as titanium (Ti), tantalum (Ta), aluminum (Al), hafnium (Hf), zirconium (Zr), lanthanoid (La), niobium (Nb), and magnesium (Mg). The second light-guiding member 62 may be configured using a dielectric material having a refractive index higher than the refractive index of the first light-guiding member 61. The second light-guiding member 62 may be configured by another metal compound, silicon nitride (SiN), silicon oxynitride (SiON), or the like. The second light-guiding member 62 may be configured by another high refractive index material.

For example, light from the optical lens is incident substantially perpendicularly on a middle part of the pixel section 100 of the imaging device 1. As in the example illustrated schematically with arrows in FIG. 4, light is obliquely incident on a peripheral part located outside the middle part, i.e., on a region distant from the middle of the pixel section 100. Therefore, the imaging device 1 is configured to allow positions of the lens 31, the filter 32, and the like in each of the pixels P to differ depending on a distance from the center of the pixel section 100, i.e., on an image height.

As illustrated in FIG. 4, for example, the lens 31 and the filter 32 of the pixel P are disposed to be shifted toward the middle of the pixel section 100, with respect to the first photoelectric conversion section 12a and the second photoelectric conversion section 12b of the pixel P. It can also be said that, in the example illustrated in FIG. 4, the lens 31 and the filter 32 are provided to be shifted rightward, with respect to the first photoelectric conversion section 12a and the second photoelectric conversion section 12b of the pixel P.

In this manner, in the imaging device 1, respective positions of the lens 31, the filter 32, and the like are adjusted depending on the image height. It is possible to suppress a decrease in the amount of light incident on the first photoelectric conversion section 12a and the second photoelectric conversion section 12b, and thus to suppress a decrease in sensitivity to incident light.

In addition, in the imaging device 1, the light-guiding wall 70 including the first light-guiding member 61 and the second light-guiding member 62 is provided above the photoelectric conversion section 12. This makes it possible to efficiently guide light having passed through different regions of the optical system to the first photoelectric conversion section 12a and the second photoelectric conversion section 12b. It is possible to suppress a decrease in the accuracy in detection of a phase difference using the first pixel signal and the second pixel signal.

In a case where the imaging device 1 does not include the second light-guiding member 62, there is a possibility that light may not be able to be efficiently guided to the photoelectric conversion section 12 in a region where the image height is high. It is conceivable that the oblique incident light is not appropriately guided, thus making it unable for a portion of the photoelectric conversion section (e.g., the first photoelectric conversion section 12a) to efficiently receive the light in the phase difference pixel. The light is not able to be efficiently guided to the first photoelectric conversion section 12a, which may cause a decrease in light separation performance in the case of being out of focus, i.e., a decrease in performance of separating the first pixel signal and the second pixel signal from each other. In particular, in the case of a fine pixel, the amount of incidence of light on the first photoelectric conversion section 12a decreases, which tends to result in a decrease in the accuracy in detection of a phase difference.

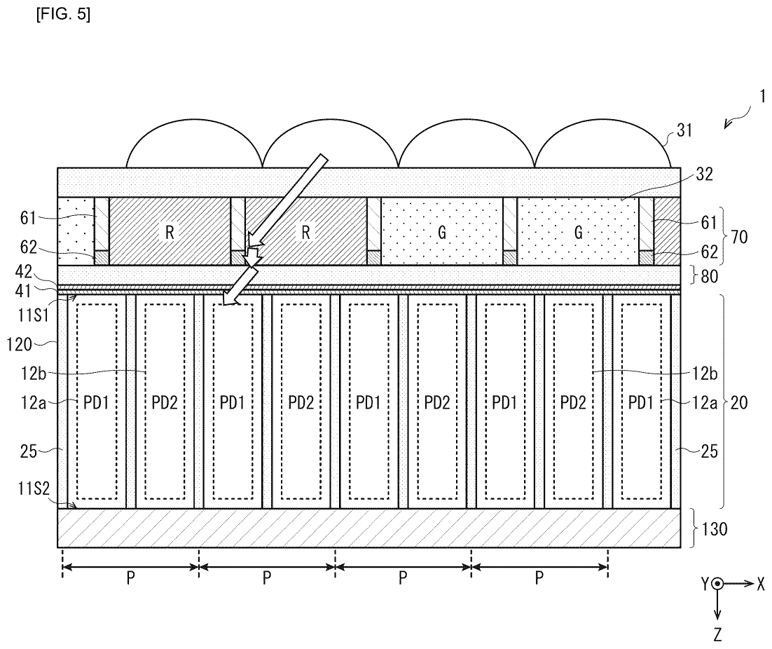

In the present embodiment, the second light-guiding member 62 changes a traveling direction of incident light in accordance with a difference in refractive indexes between the second light-guiding member 62 and a medium therearound. As in the example illustrated in FIG. 5, the second light-guiding member 62 having a relatively high refractive index causes light incident on the second light-guiding member 62 from above via the lens 31 to travel toward the first photoelectric conversion section 12a. Providing the second light-guiding member 62 makes it possible to condense the light on the first photoelectric conversion section 12a.

It can also be said that the imaging device 1 has a waveguide structure that causes the first light-guiding member 61 and the second light-guiding member 62 to guide light to the first photoelectric conversion section 12a and the second photoelectric conversion section 12b. It is possible to cause the second light-guiding member 62 to appropriately guide light from the optical system and to be incident on the first photoelectric conversion section 12a.

It is therefore possible for the first photoelectric conversion section 12a and the second photoelectric conversion section 12b to efficiently receive light having passed through different regions of the optical system, thus enabling pupil division to be appropriately performed. It becomes possible to suppress a decrease in the accuracy in detection of a phase difference using the first pixel signal and the second pixel signal. In particular, also in the case of a fine pixel, it is possible for the first light-guiding member 61 and the second light-guiding member 62 to appropriately guide incident light, thus enabling accurate detection of a phase difference.

Thus, in the imaging device 1 according to the present embodiment, it is possible to suppress a decrease in performance of separating the first pixel signal and the second pixel signal from each other. It becomes possible to suppress a decrease in the accuracy in detection of a phase difference, thus making it possible to prevent a decrease in AF performance. In particular, also in the case of a fine pixel, it is possible to secure the performance of separating the first pixel signal and the second pixel signal from each other. It becomes possible to improve the AF performance, and thus to improve the image quality of an image.

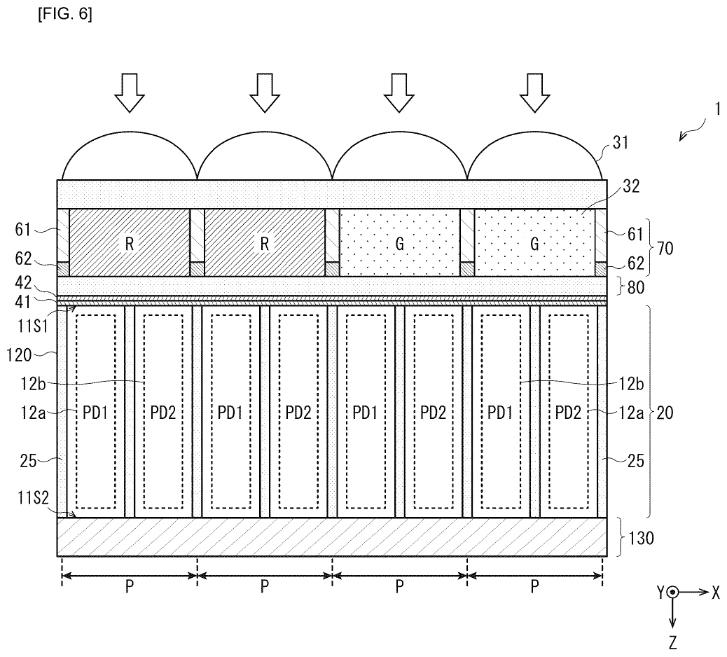

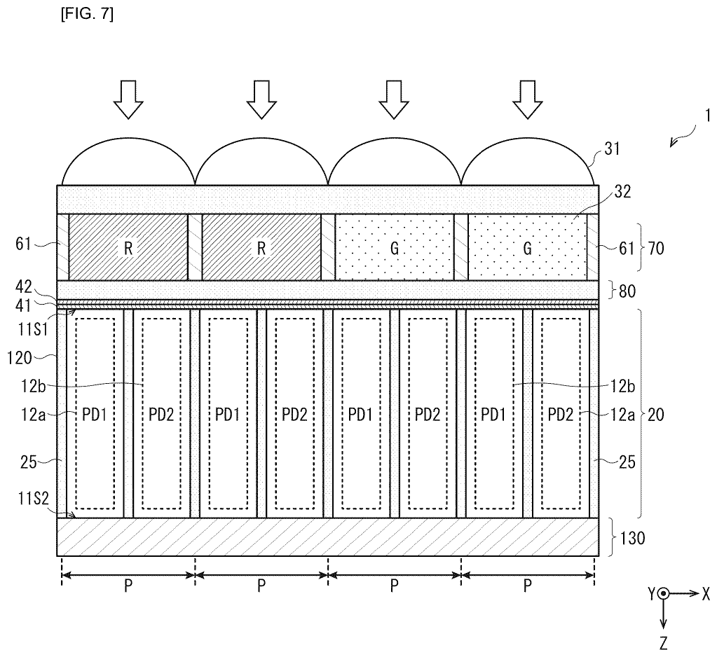

It is to be noted that, in a middle region of the pixel section 100 (light-receiving section 20), the pixel P is configured as illustrated in FIG. 6, for example. In the pixel P in the middle of the pixel section 100, for example, the center position of each of the lens 31 and the filter 32 and the center position of a part (the separation section 25 in FIG. 6) between the first photoelectric conversion section 12a and the second photoelectric conversion section 12b substantially coincide with each other, as in the example illustrated in FIG. 6. It is to be noted that, in each of the pixels P in the middle region of the pixel section 100, the second light-guiding member 62 may not be provided, as in the example illustrated in FIG. 7.

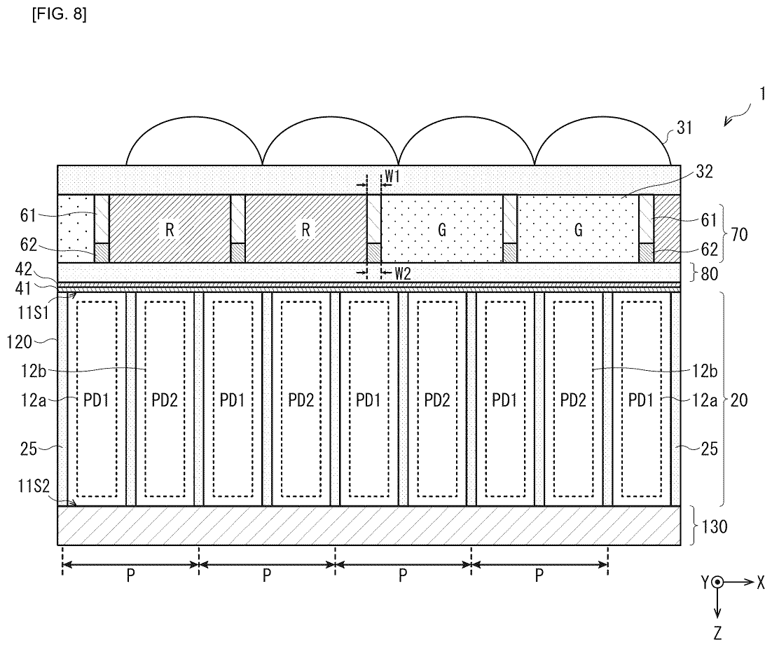

FIG. 8 is an explanatory diagram of an example of a cross-sectional configuration of an imaging device according to the embodiment. As illustrated in FIG. 8, a width (area) of the second light-guiding member 62 may be substantially equal to a width of the first light-guiding member 61. For example, a width W2 of the second light-guiding member 62 in the X-axis direction (or Y-axis direction) may be substantially the same as a width W1 of the first light-guiding member 61. The width (area) of the second light-guiding member 62 may differ from the width (area) of the first light-guiding member 61.

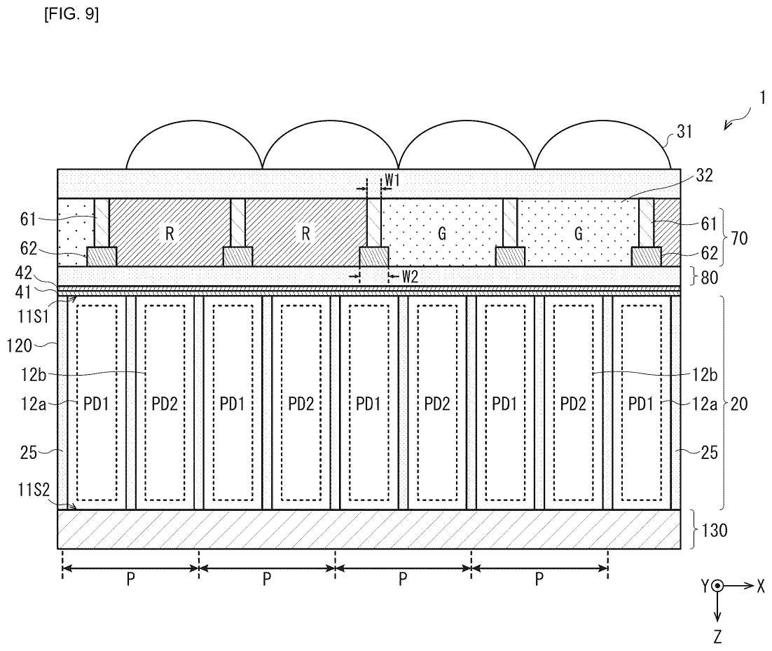

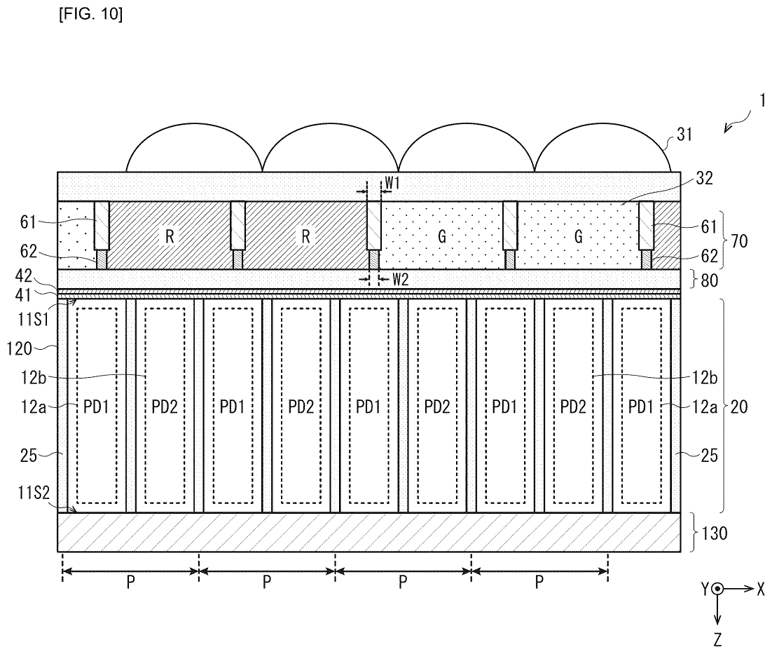

FIGS. 9 and 10 are each an explanatory diagram of another example of the cross-sectional configuration of an imaging device according to the embodiment. For example, as in the example illustrated in FIG. 9, the width W2 of the second light-guiding member 62 in the X-axis direction (or Y-axis direction) may be larger than the width W1 of the first light-guiding member 61. In addition, for example, the width W2 of the second light-guiding member 62 may be smaller than the width W1 of the first light-guiding member 61, as in the example illustrated in FIG. 10.

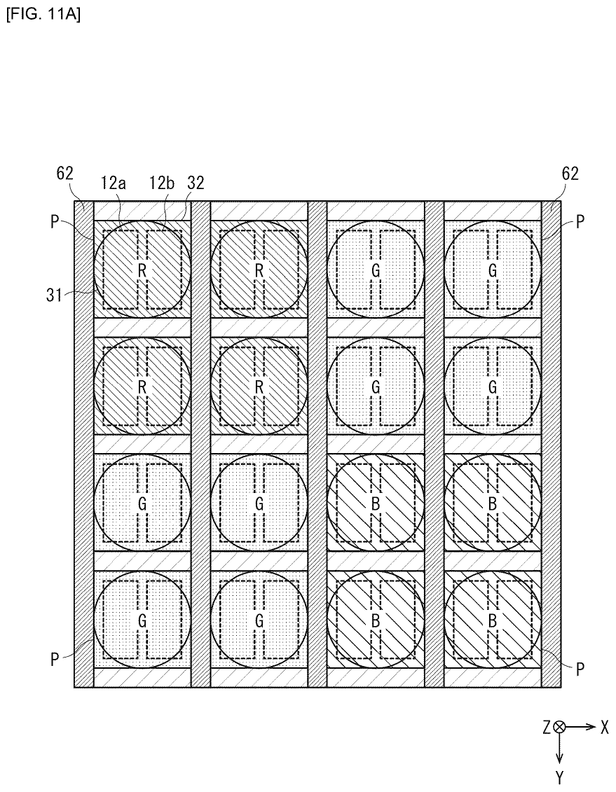

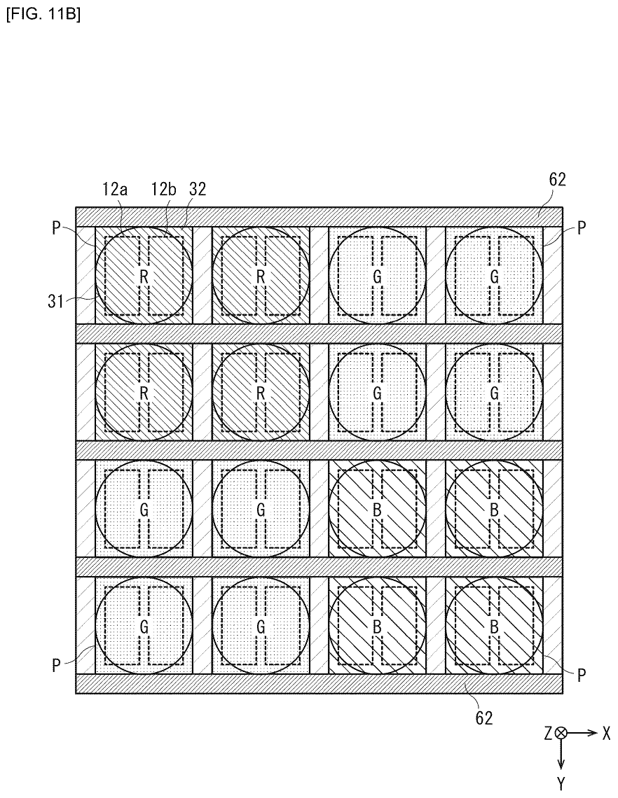

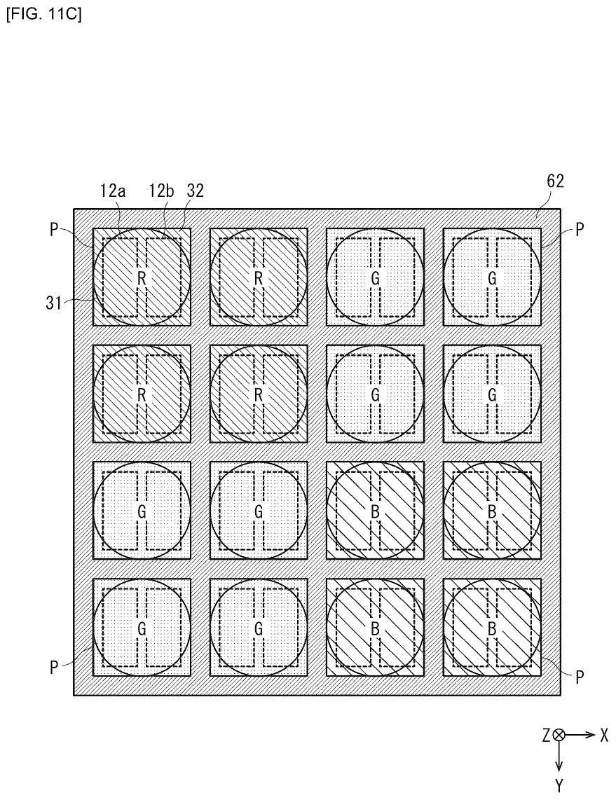

FIGS. 11A and 11B are each an explanatory diagram of an example of a planar configuration of an imaging device according to the embodiment. In the pixel section 100 of the imaging device 1, the second light-guiding member 62 may be provided between the filters 32 adjacent to each other in the X-axis direction, as in the example illustrated in FIG. 11A. For example, in a region of the pixel section 100 distant from the middle part of the pixel section 100 in a ±X-direction, the second light-guiding member 62 may be provided as in the example illustrated in FIG. 11A. In the example illustrated in FIG. 11A, a plurality of second light-guiding members 62 having a shape extending in the Y-axis direction is arranged side by side in the X-axis direction.

In the pixel section 100, the second light-guiding member 62 may be provided between the filters 32 adjacent to each other in the Y-axis direction, as in the example illustrated in FIG. 11B. For example, in a region of the pixel section 100 distant from the middle part of the pixel section 100 in a ±Y-direction, the second light-guiding member 62 may be provided, as in the example illustrated FIG. 11B. In the example illustrated in FIG. 11B, the plurality of second light-guiding members 62 having a shape extending in the X-axis direction is arranged side by side in the Y-axis direction.

It is to be noted that the shape and arrangement of the second light-guiding members 62 are not limited to the example described above, and may be changed as appropriate. The second light-guiding members 62 may be disposed for each of the pixels P, or may be provided for a plurality of pixels P. In addition, the second light-guiding member 62 may be provided to surround the periphery of the filter 32 in a plan view, as in the example illustrated in FIG. 11C. The second light-guiding member 62 may be formed in a grid pattern along boundaries between the pixels P.

### Workings and Effects

The light detecting device according to the present embodiment includes: a first pixel (e.g., G pixel) and a second pixel (e.g., R pixel) each including a first photoelectric conversion element (photoelectric conversion section 12) that photoelectrically converts light; a first filter (filter 32) provided in a manner corresponding to the first pixel; a second filter provided in a manner corresponding to the second pixel; a first light-guiding member (first light-guiding member 61) provided between the first filter and the second filter; and a second light-guiding member (second light-guiding member 62) provided around the first light-guiding member and having a refractive index higher than a refractive index of the first light-guiding member.

In the light detecting device (imaging device 1) according to the present embodiment, the second light-guiding member 62 having a refractive index higher than a refractive index of the first light-guiding member 61 is provided around the first light-guiding member 61. It is therefore possible to cause the second light-guiding member 62 to appropriately guide incident light, thus making it possible to suppress a decrease in the accuracy of detection of light. It is possible to achieve a light detecting device having favorable detection performance.

Next, a description is given of modification examples of the present disclosure. Hereinafter, components similar to those of the foregoing embodiment are denoted by the same reference numerals, and descriptions thereof are omitted as appropriate.

### 2. Modification Examples

### (2-1. Modification Example 1)

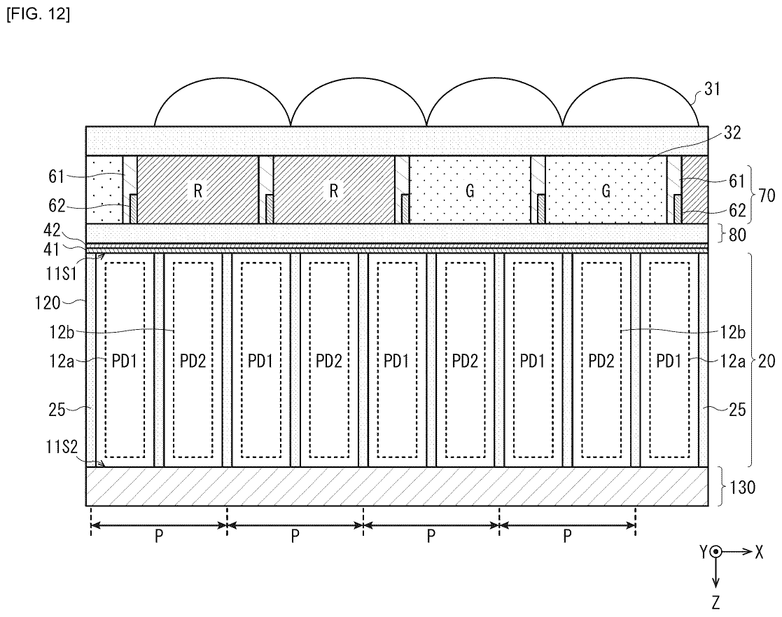

The description has been given, in the above-described embodiment, of the configuration examples of the second light-guiding member 62 and the light-guiding wall 70; however, the configurations of the second light-guiding member 62 and the light-guiding wall 70 are not limited to the above-described examples. FIG. 12 is an explanatory diagram of a configuration example of an imaging device according to Modification Example 1 of the present disclosure. The second light-guiding member 62 may be provided along the side surface of the filter 32, as in the example illustrated in FIG. 12. It can also be said that the second light-guiding member 62 has a shape along a waveguide and is disposed along the waveguide.

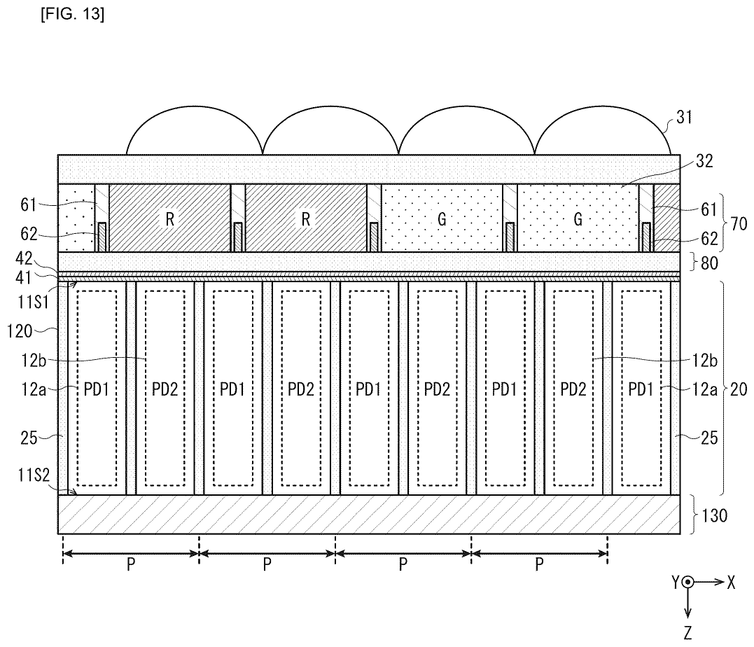

FIGS. 13 to 15 are each an explanatory diagram of another configuration example of the imaging device according to Modification Example 1 of the present disclosure. At least a portion of the second light-guiding member 62 may be provided in the first light-guiding member 61. For example, as in the example illustrated in FIG. 13, the second light-guiding member 62 may be disposed to be embedded in the first light-guiding member 61. In the example illustrated in FIG. 13, the first light-guiding member 61 is provided to cover the second light-guiding member 62.

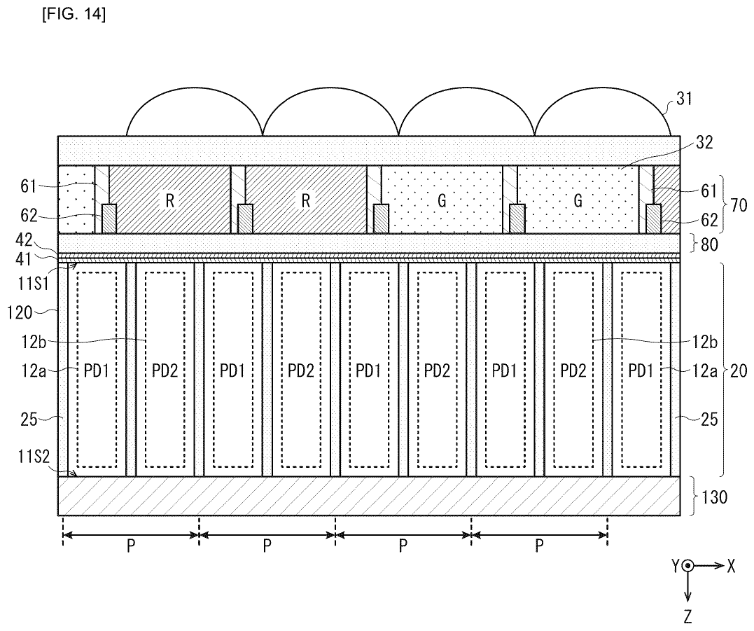

As in the example illustrated in FIG. 14, a portion of the second light-guiding member 62 may be disposed in the first light-guiding member 61. It can also be said that the second light-guiding member 62 may be provided to replace a portion of the filter 32 and a portion of the first light-guiding member 61. It is to be noted that a portion of the second light-guiding member 62 may be formed in the insulating layer 80, and the bottom of the second light-guiding member 62 may be positioned in the insulating layer 80.

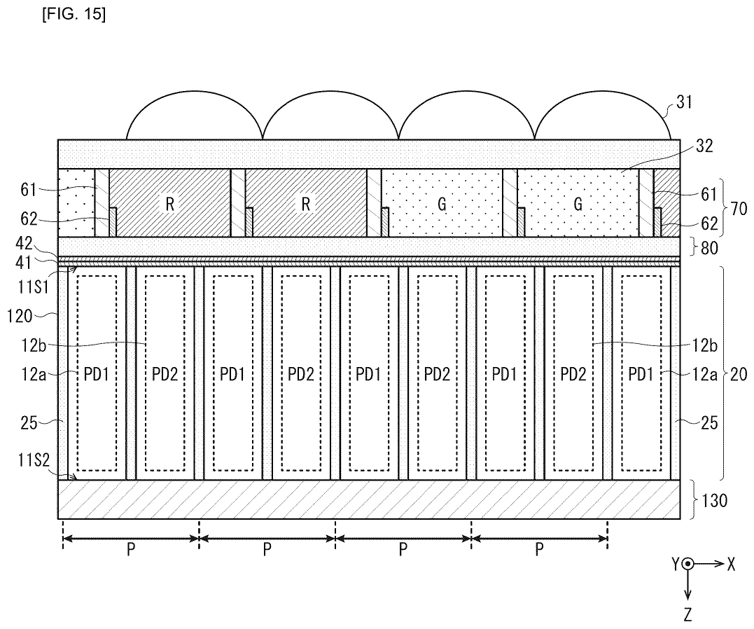

In addition, for example, as in the example illustrated in FIG. 15, the second light-guiding member 62 may be provided to be adjacent to the first light-guiding member 61. The second light-guiding member 62 may be disposed adjacent to the first light-guiding member 61. In the example illustrated in FIG. 15, the second light-guiding member 62 is disposed to be in contact with a side surface (side part) of the first light-guiding member 61.

Also in the case of the imaging device 1 according to the present modification example, it is possible to cause the second light-guiding member 62 to appropriately guide incident light. It is possible to appropriately perform pupil division, and thus to suppress a decrease in the accuracy in detection of a phase difference. It becomes possible to achieve a light detecting device (imaging device) having favorable detection performance.

### (2-2. Modification Example 2)

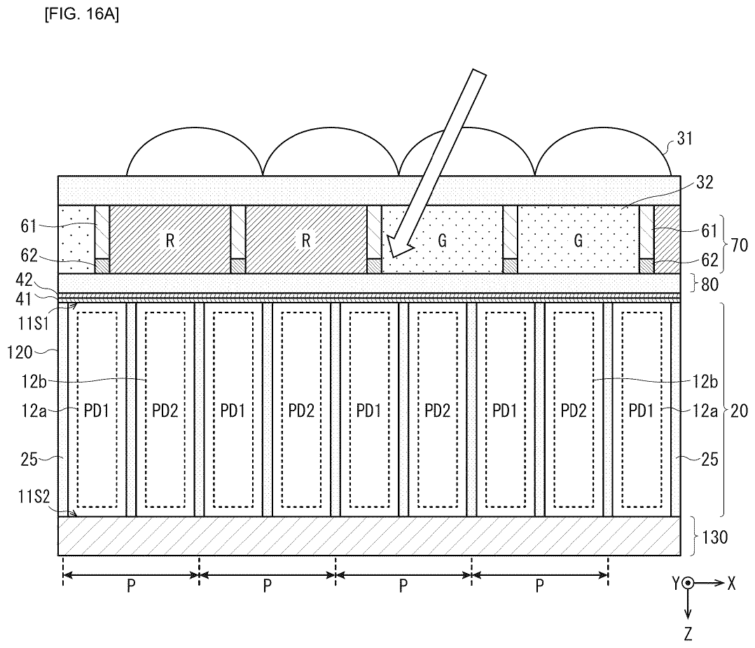

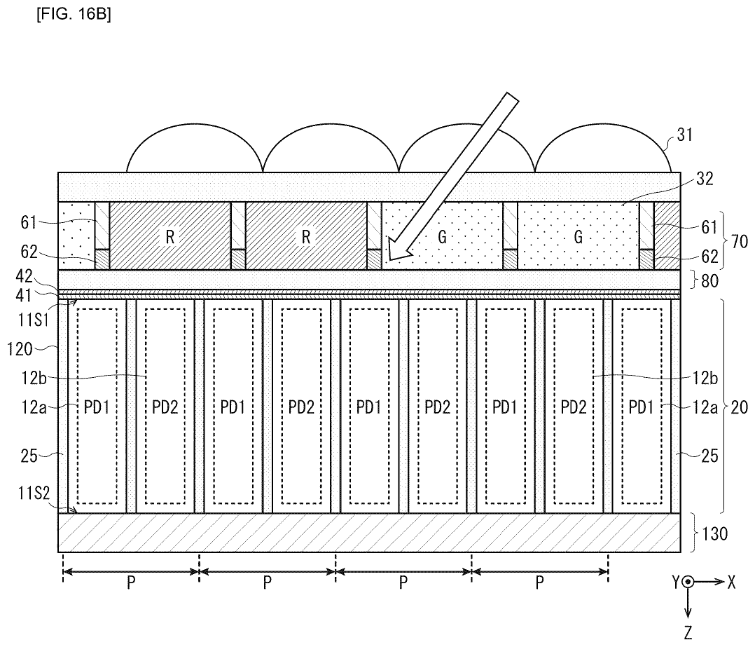

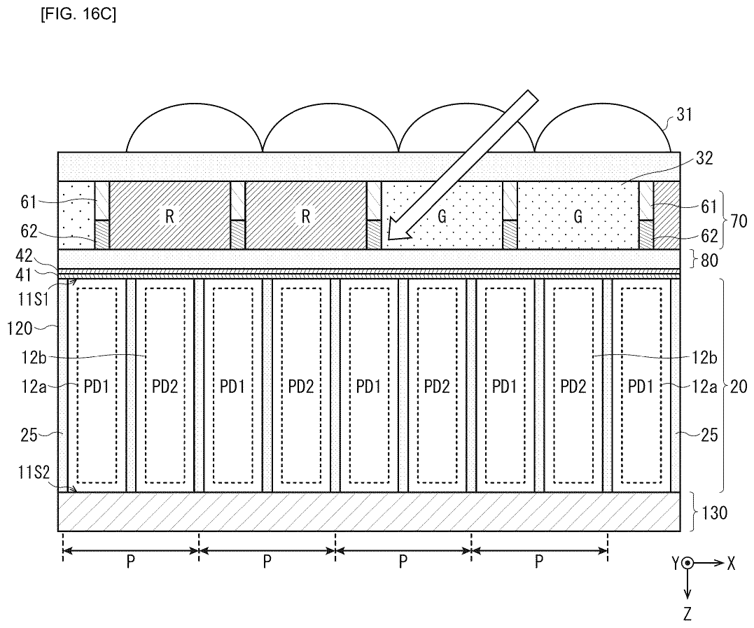

FIGS. 16A to 16C are each an explanatory diagram of a configuration example of pixels at positions of different image heights of an imaging device according to Modification Example 2. FIG. 16B illustrates a configuration example of pixels in a region where the image height is higher than the case of FIG. 16A. In addition, FIG. 16C illustrates a configuration example of pixels in a region where the image height is higher than the case of FIG. 16B.

The imaging device 1 may be configured to allow the size (height, width, etc.) of the second light-guiding member 62 in each of the pixels P to differ depending on a distance from the center of the pixel section 100 (pixel array), i.e., on the image height. As an example, as illustrated in FIGS. 16A to 16C, a configuration may be adopted to allow the height (length) of the second light-guiding member 62 in each of the pixels P to differ depending on the image height. For example, as in the example illustrated in FIGS. 16A to 16C, the second light-guiding member 62 in a region located more distant from the middle of the pixel section 100 has a higher height in the region.

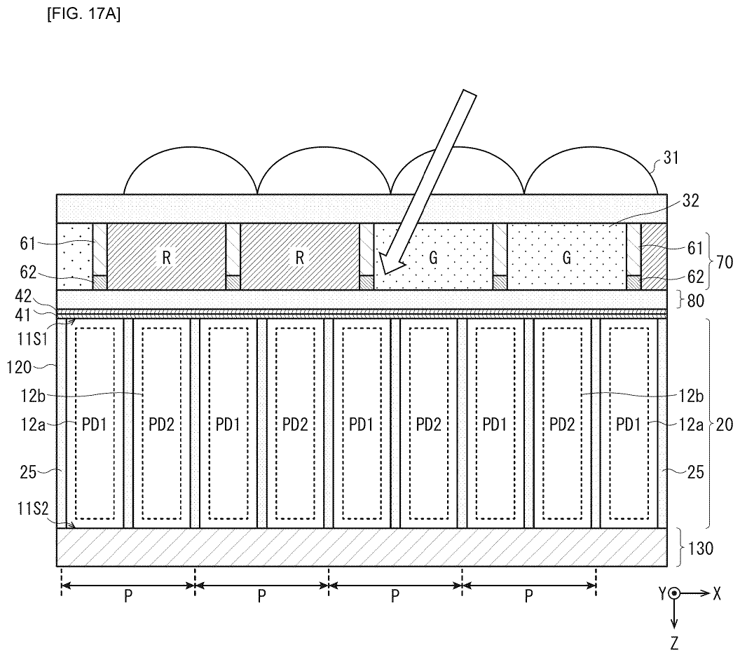

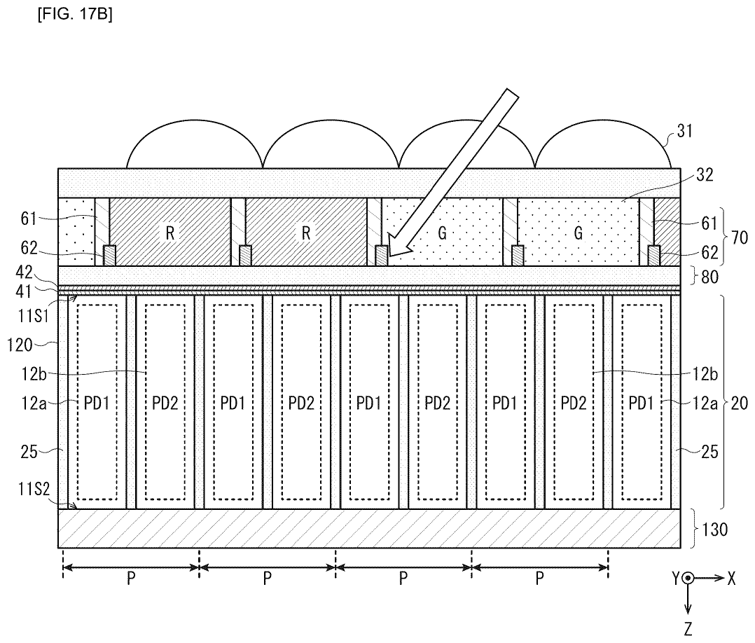

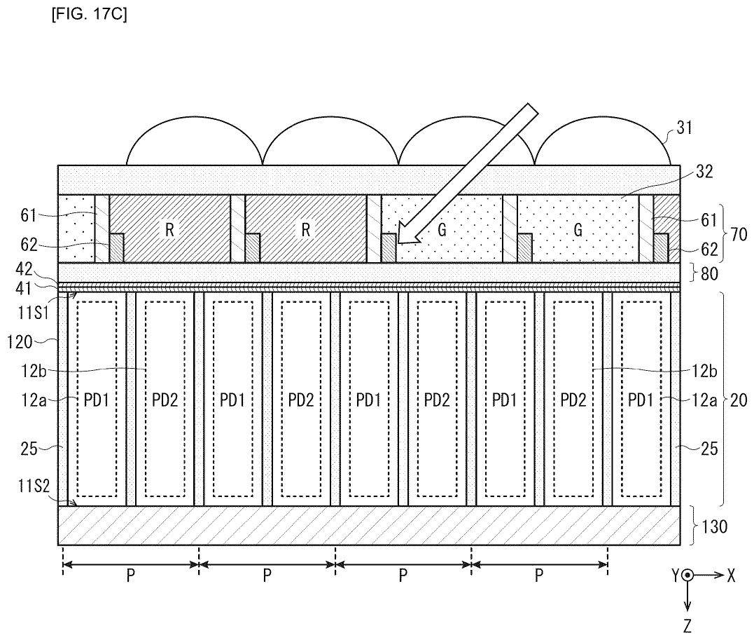

FIGS. 17A to 17C are each an explanatory diagram of another configuration example of pixels at positions of different image heights of the imaging device according to Modification Example 2. FIG. 17B illustrates a configuration example of pixels in a region where the image height is higher than the case of FIG. 17A. In addition, FIG. 17C illustrates a configuration example of pixels in a region where the image height is higher than the case of FIG. 17B.

As in the example illustrated in FIGS. 17A to 17C, the imaging device 1 may be configured to allow the shape and arrangement position of the second light-guiding member 62 in each of the pixels P to differ depending on the distance from the center of the pixel section 100, i.e., on the image height. It is to be noted that each of the pixels P of the middle part of the pixel section 100 may include the second light-guiding member 62. Also in the case of the present modification example, it is possible to obtain effects similar to those of the imaging device of the foregoing embodiment.

### (2-3. Modification Example 3)

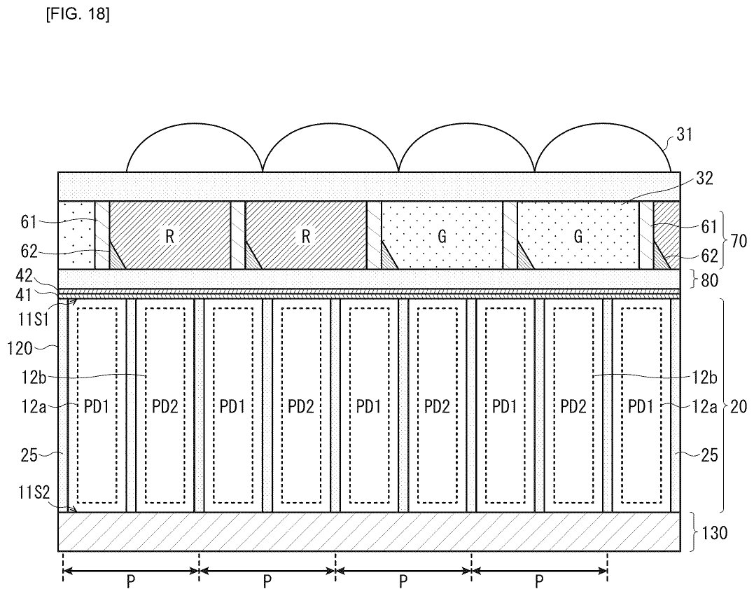

The foregoing embodiment and modification examples have described the configuration examples of the imaging device 1, which, however, are merely exemplary; the configuration of the imaging device 1 is not limited to the above-described example. FIG. 18 is an explanatory diagram of a configuration example of an imaging device according to Modification Example 3. The second light-guiding member 62 may have a tapered structure, as illustrated in FIG. 18.

The second light-guiding member 62 has a tapered part (inclined part), and has a tapered shape. In the example illustrated in FIG. 18, the widths of the second light-guiding member 62 in the X-axis direction and the Y-axis direction become wider as being closer to the insulating layer 80. It is to be noted that the second light-guiding member 62 may have a trapezoidal shape.

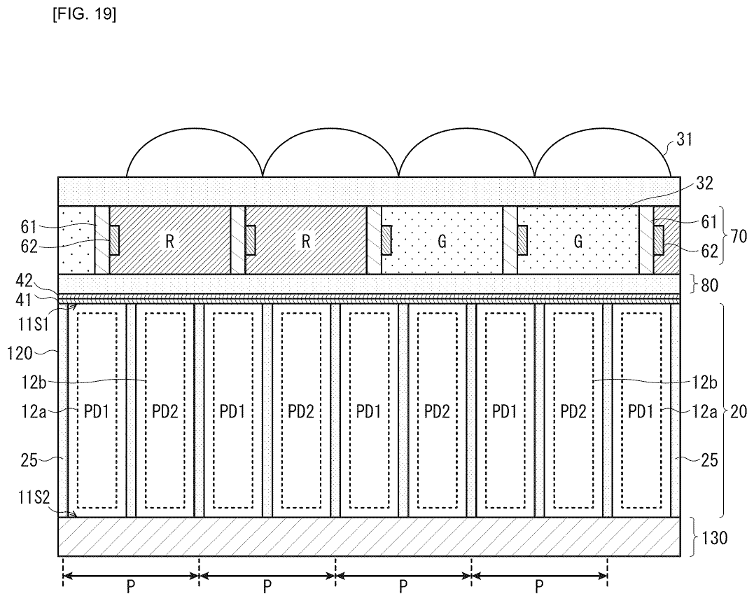

FIG. 19 is an explanatory diagram of another configuration example of the imaging device according to Modification Example 3. The second light-guiding member 62 may be disposed to be distant from the insulating layer 80. The second light-guiding member 62 may be disposed to be embedded in the filter 32, for example, as in the example illustrated in FIG. 19. The second light-guiding member 62 is in a state of being floated to be distant from the insulating layer 80.

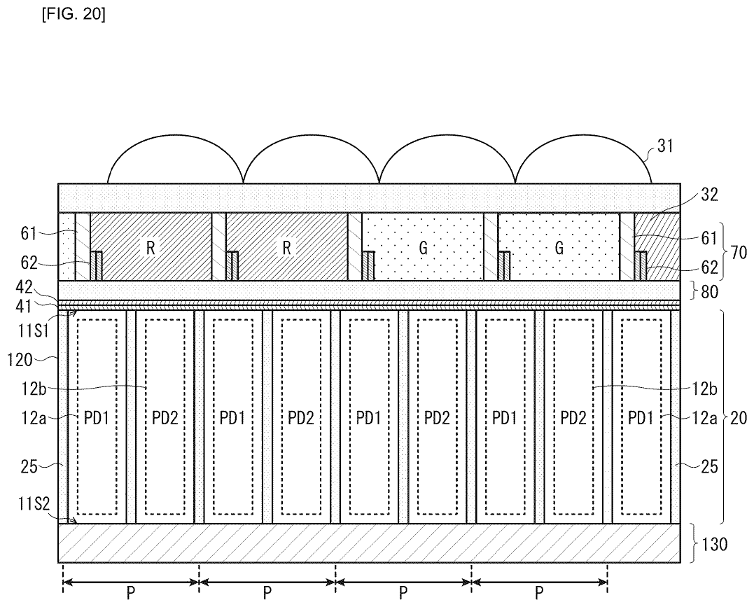

It is to be noted that the configuration of the second light-guiding member 62 is not limited to the above-described example, and may be changed as appropriate. For example, the second light-guiding member 62 may have a configuration in which a plurality of films is stacked, as in the example schematically illustrated in FIG. 20. For example, the second light-guiding member 62 may be configured by films of a plurality of layers having different refractive indexes. The second light-guiding member 62 may have a stacked structure of two layers or three layers or more, for example.

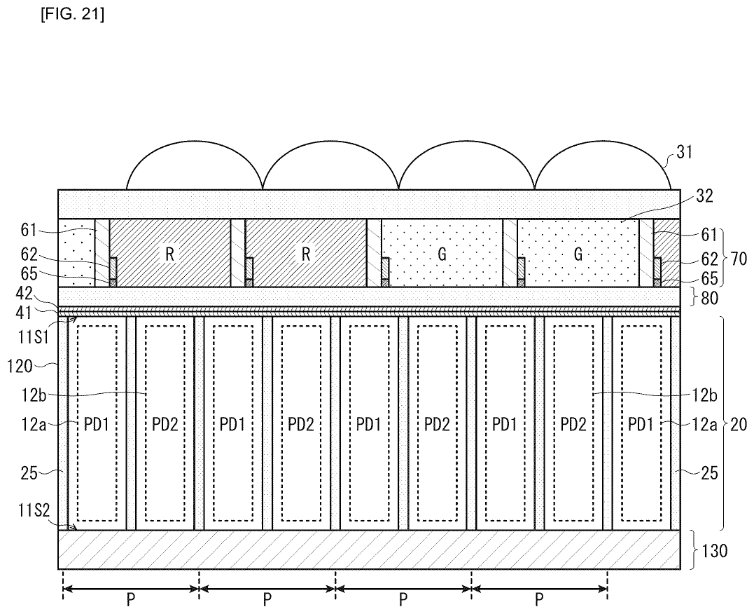

As illustrated in FIG. 21, the imaging device 1 may include a stopper film 65 between the second light-guiding member 62 and the insulating layer 80. The second light-guiding member 62 may include an etching stopper film 65. Also in the case of the present modification example, it is possible to obtain effects similar to those of the imaging device of the foregoing embodiment.

### (2-4. Modification Example 4)

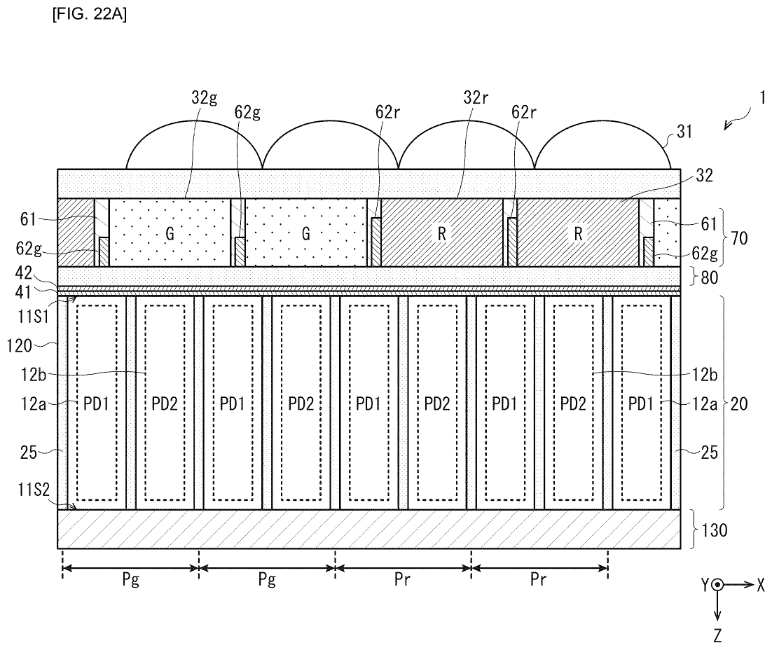

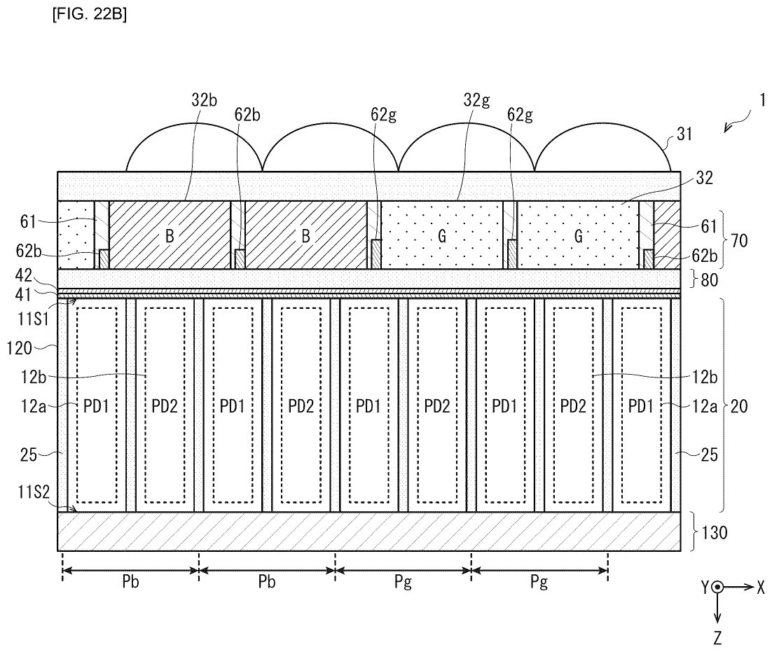

FIGS. 22A and 22B are each an explanatory diagram of a configuration example of an imaging device according to Modification Example 4. In the same manner as FIG. 4, FIG. 22A illustrates a plurality of pixels (pixels Pr) each provided with the filter 32 (a filter 32r) that transmits red (R) light and a plurality of pixels (pixels Pg) each provided with the filter 32 (a filter 32g) that transmits green (G) light. FIG. 22B illustrates the plurality of pixels Pg and a plurality of pixels (pixels Pb) each provided with the filter 32 (a filter 32b) that transmits B (blue) light.

The imaging device 1 may include the second light-guiding member 62 (a second light-guiding member 62r) provided for the filter 32r, the second light-guiding member 62 (a second light-guiding member 62g) provided for the filter 32g, and the second light-guiding member 62 (a second light-guiding member 62b) provided for the filter 32b to allow respective shapes, arrangement positions, and the like to differ from one another. For example, the second light-guiding member 62r, the second light-guiding member 62g, and the second light-guiding member 62b may differ from one another in terms of respective sizes, refractive indexes, and the like, in order to obtain desired separation performance for each of pixels of R, G, and B.

In consideration of the refractive indexes of the respective filters 32 of R, G, and B, the second light-guiding member 62r, the second light-guiding member 62g, and the second light-guiding member 62b may be configured by materials having refractive indexes different from one another. For example, the second light-guiding member 62r may be configured by a material having a refractive index higher than a refractive index of each of the second light-guiding member 62g and the second light-guiding member 62b.

For example, the second light-guiding member 62r has a refractive index higher than the refractive index of each of the second light-guiding member 62g and the second light-guiding member 62b. In addition, the second light-guiding member 62g may be configured by a material having a refractive index higher than the refractive index of the second light-guiding member 62b to have a refractive index higher than the refractive index the second light-guiding member 62b.

In addition, for example, as illustrated in FIG. 22A, a height of the second light-guiding member 62r (a height of the second light-guiding member 62r in the Z-axis direction) provided to be in contact with the filter 32r may be larger than a height of the second light-guiding member 62g provided to be in contact with the filter 32g. In addition, as illustrated in FIG. 22B, the height of the second light-guiding member 62g may be larger than a height of the second light-guiding member 62b provided to be in contact with the filtering 32b. It is to be noted that the second light-guiding member 62b may be omitted, as needed.

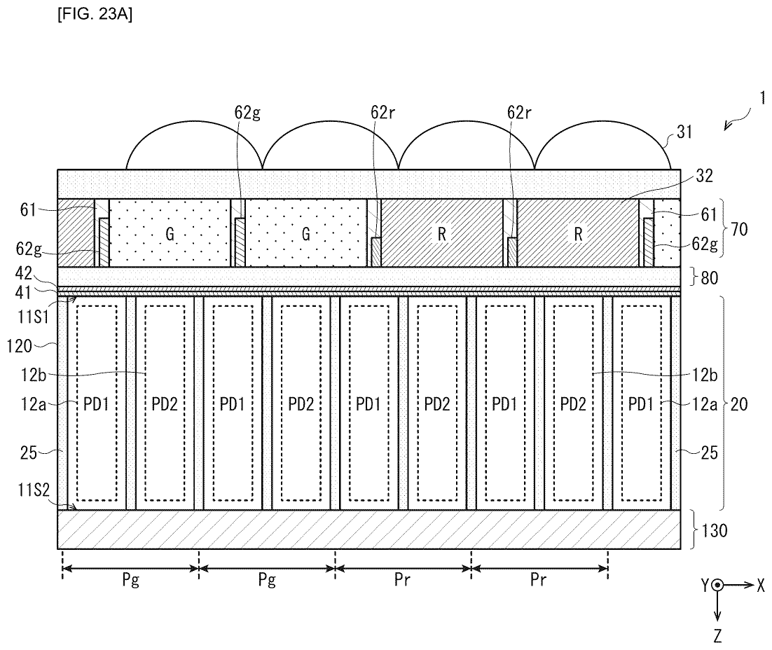

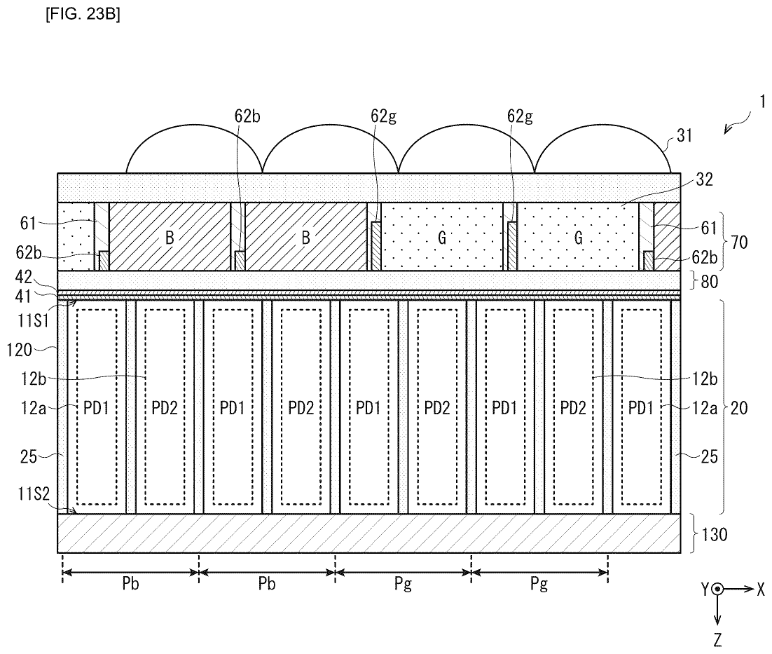

FIGS. 23A and 23B are each an explanatory diagram of another configuration example of the imaging device according to Modification Example 4. For example, in consideration of characteristics of human eyes, the height of the second light-guiding member 62g may be larger than the height of each of the second light-guiding member 62r and the second light-guiding member 62b, as illustrated in FIGS. 23A and 23B. It is to be noted that the second light-guiding member 62r may be formed to be larger than the height of the second light-guiding member 62b.

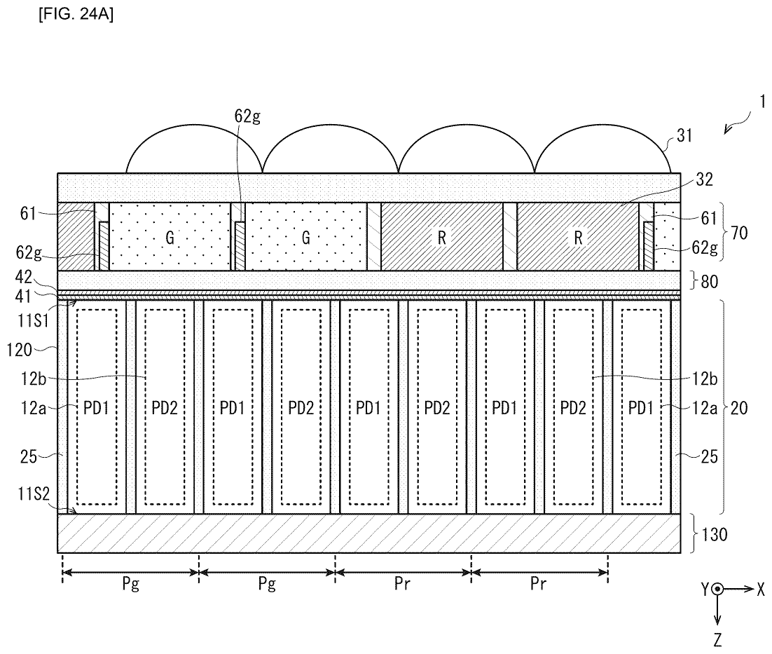

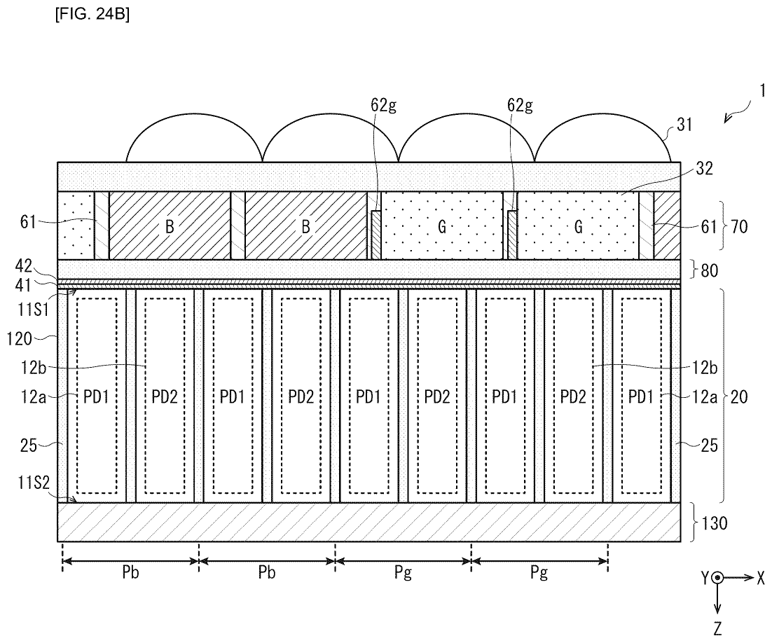

It is to be noted that the second light-guiding member 62 may be provided only for one or two types of the filter 32, among the filter 32r, the filter 32g, and the filter 32b. For example, as in the example illustrated in FIG. 24 A and 24B, the imaging device 1 may be configured to include only the second light-guiding member 62g, among the second light-guiding member 62r, the second light-guiding member 62g, and the second light-guiding member 62b. In addition, for example, the imaging device 1 may be configured to include the second light-guiding member 62r and the second light-guiding member 62g, among the second light-guiding member 62r, the second light-guiding member 62g, and the second light-guiding member 62b.

It is to be noted that the second light-guiding member 62 may be disposed only for some of the pixels of the imaging device 1. For example, the second light-guiding member 62 may be disposed only for one or two types of the pixels P, among the pixel Pr, the pixel Pg, and the pixel Pb.

### (2-5. Modification Example 5)

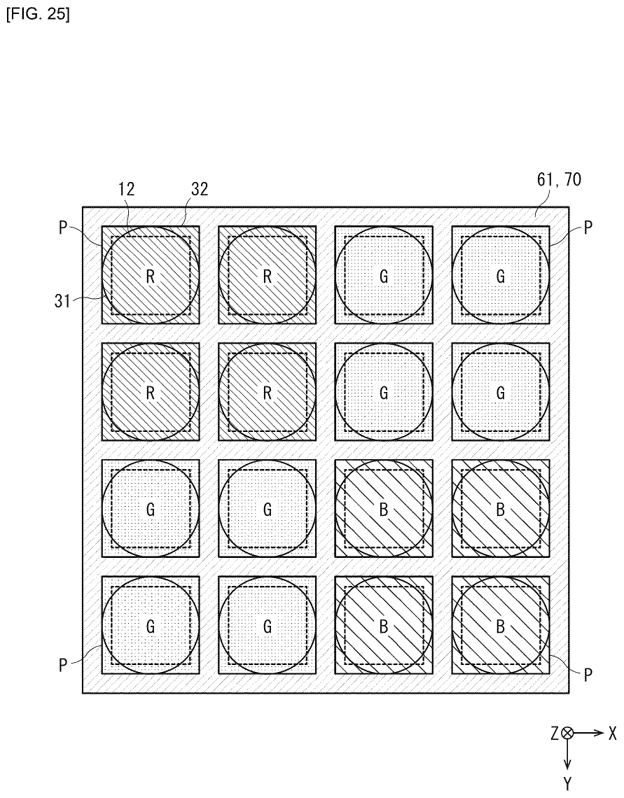

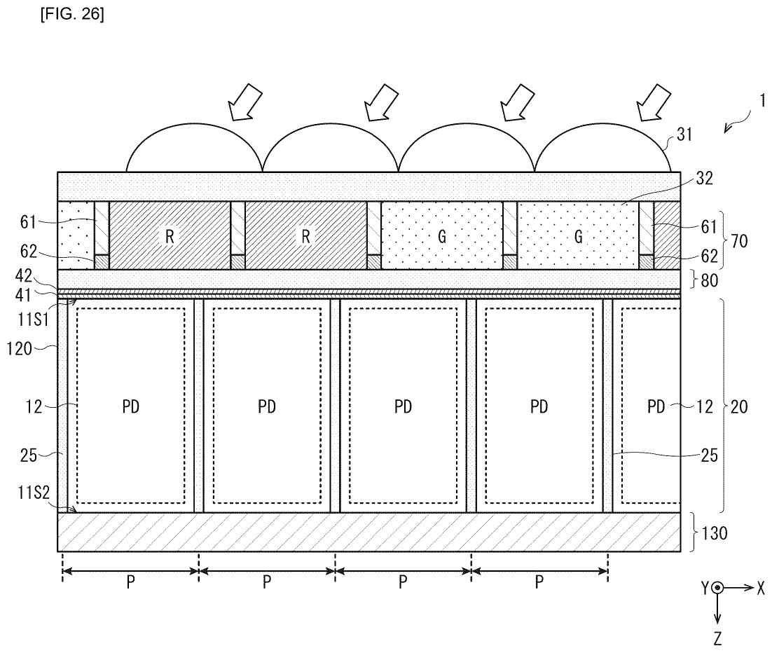

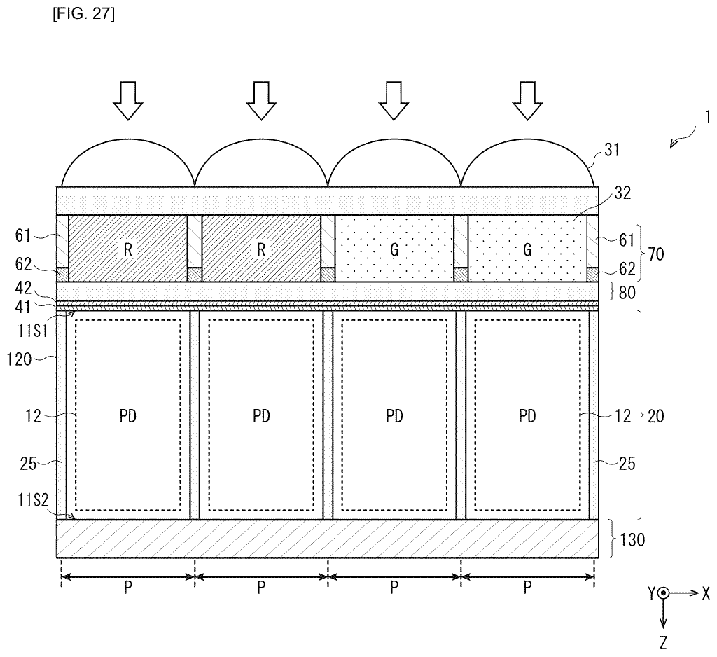

The descriptions have been given, in the foregoing embodiment and modification examples, of the configuration examples of the pixel P of the imaging device 1, but the configuration of the pixel P is not limited to the above-descried example. FIG. 25 is an explanatory diagram of an example of a planar configuration of an imaging device according to Modification Example 5. FIGS. 26 and 27 are each an explanatory diagram of an example of a cross-sectional configuration of the imaging device according to Modification Example 5.

FIG. 26 illustrates an example of a cross-sectional configuration in a region where a distance from the center of the pixel section 100 (pixel array), i.e., the image height is high. FIG. 27 illustrates an example of a cross-sectional configuration in a region near the center of the pixel section 100. As illustrated in FIGS. 25 to 27, each of the pixels P may include one photoelectric conversion section 12.

In the imaging device 1 according to the present modification example, for example, one lens 31 (lens section) and the filter 32 are provided for one photoelectric conversion section 12. The second light-guiding member 62 may be provided for each of the filters 32 or for every plurality of filters 32. It is to be noted that, in each of the pixel P in the middle region of the pixel section 100, the second light-guiding member 62 may not be provided.

Also in the case of the imaging device 1 according to the present modification example, providing the second light-guiding member 62 enables incident light to be appropriately guided to the photoelectric conversion section 12. It is possible to suppress deterioration in the quality of the pixel signal, and thus to suppress deterioration in the image quality of an image. It is possible to achieve a light detecting device having favorable detection performance.

### 3. Application Example

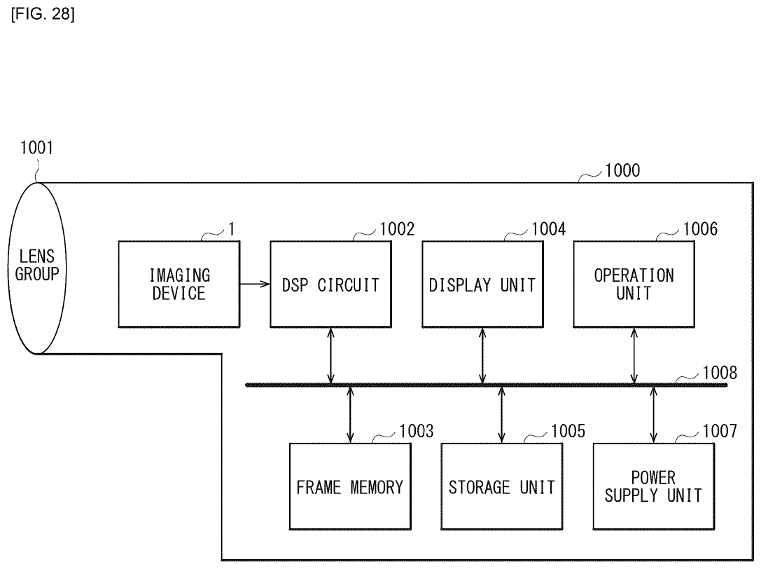

The above-described imaging device 1 or the like is applicable, for example, to any type of electronic apparatus with an imaging function including a camera system such as a digital still camera or a video camera, a mobile phone having an imaging function, and the like. FIG. 28 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject, and forms an image on an imaging surface of the imaging device 1. The imaging device 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic EL (Electro Luminescence) panel, and records image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### Example of Practical Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

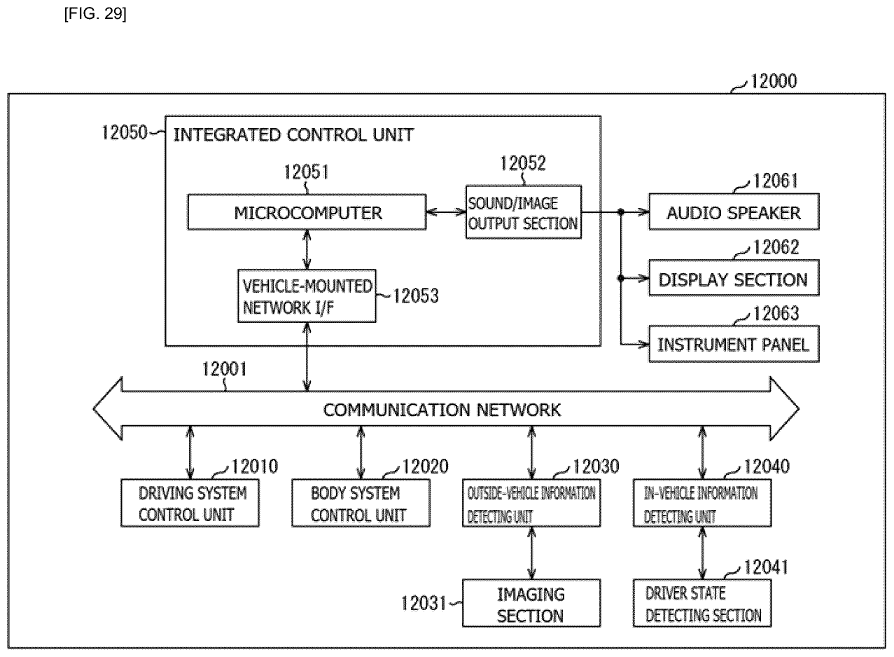

FIG. 29 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 29, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 29, an audio speaker 12061, a display section 12062, and an instrument panel 12063 are illustrated as the output device. The display section 12062 may, for example, include at least one of an on-board display and a head-up display.

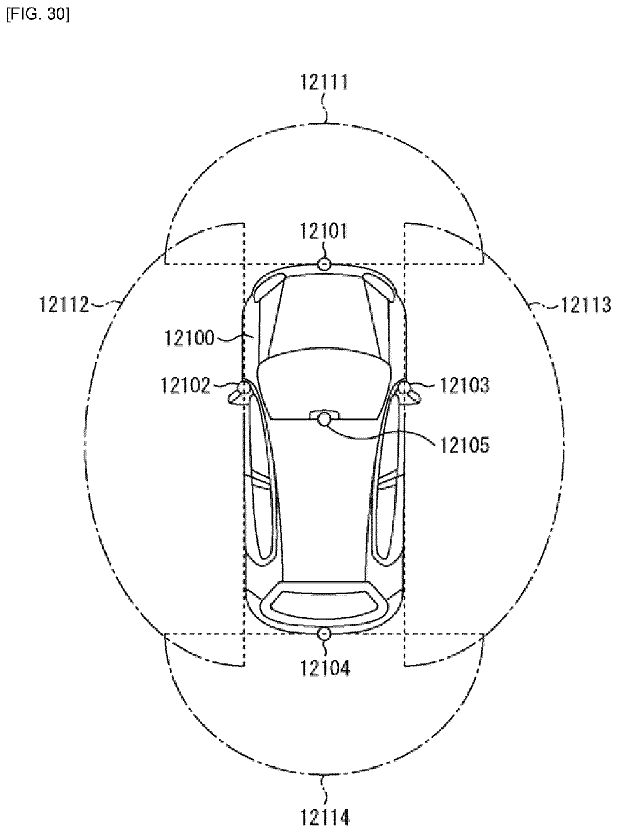

FIG. 30 is a diagram depicting an example of the installation position of the imaging section 12031.

In FIG. 30, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 30 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 or the like can be applied to the imaging section 12031. Applying the technology according to an embodiment of the present disclosure to the imaging section 12031 enables obtainment of a photographed image having high definition. It is possible to perform highly accurate control utilizing the photographed image in the mobile body control system.

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

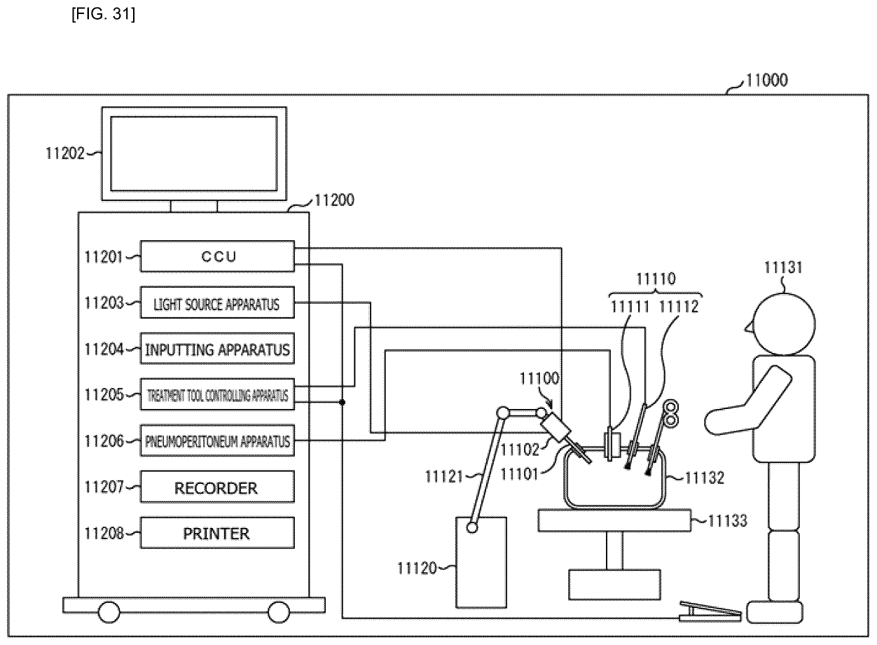

FIG. 31 is a view depicting an example of a schematic configuration of an endoscopic surgery system to which the technology according to an embodiment of the present disclosure (present technology) can be applied.

In FIG. 31, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

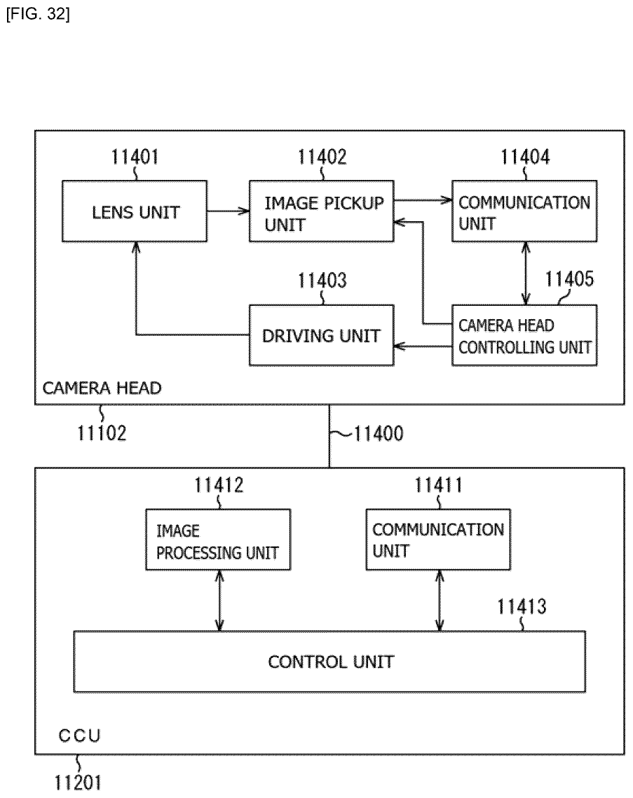

FIG. 32 is a block diagram depicting an example of a functional configuration of the camera head 11102 and the CCU 11201 depicted in FIG. 31.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 makes it possible to provide the endoscope 11100 having high definition.

Although the description has been given hereinabove of the present disclosure with reference to the embodiments, the modification examples, the application example, and the practical application examples, the present technology is not limited to the foregoing embodiments and the like, and may be modified in a wide variety of ways. For example, although the foregoing modification examples have been described as modification examples of the foregoing embodiments, the configurations of the respective modification examples may be combined as appropriate.

In the foregoing embodiment and the like, the description has been given by exemplifying the imaging device. However, it is sufficient for the light detecting device of the present disclosure, for example, to receive incident light and convert the light into electric charge. The signal to be outputted may be a signal of image information or a signal of distance measurement information. The light detecting device (imaging device) is applicable to an image sensor, a distance measuring sensor, or the like.

The light detecting device according to the present disclosure is applicable as a distance measuring sensor that is able to perform distance measurement of a TOF (Time Of Flight) method. The light detecting device (imaging device) is also applicable as a sensor that is able to detect an event, e.g., an event-driven type sensor (called EVS (Event Vision Sensor), EDS (Event Driven Sensor), DVS (Dynamic Vision Sensor), etc.).

A light detecting device according to an embodiment of the present disclosure includes: a first pixel and a second pixel each including a first photoelectric conversion element; a first filter provided in a manner corresponding to the first pixel; a second filter provided in a manner corresponding to the second pixel; a first light-guiding member provided between the first filter and the second filter; and a second light-guiding member provided around the first light-guiding member and having a refractive index higher than a refractive index of the first light-guiding member. This makes it possible to achieve a light detecting device having favorable detection performance.

It is to be noted that the effects described herein are merely exemplary and are not limited to the description, and may further include other effects. In addition, the present disclosure may also have the following configurations.
(1)

A light detecting device including:
a first pixel and a second pixel each including a first photoelectric conversion element that photoelectrically converts light;
a first filter provided in a manner corresponding to the first pixel;
a second filter provided in a manner corresponding to the second pixel;
a first light-guiding member provided between the first filter and the second filter; and
a second light-guiding member provided around the first light-guiding member, the second light-guiding member having a refractive index higher than a refractive index of the first light-guiding member.
(2)

The light detecting device according to (1), in which at least a portion of the second light-guiding member is provided on a side of the first filter opposite to a side on which light is incident.
(3)

The light detecting device according to (1) or (2), in which at least a portion of the second light-guiding member is provided between the first light-guiding member and the first photoelectric conversion element.
(4)

The light detecting device according to any one of (1) to (3), in which at least a portion of the second light-guiding member is provided in the first light-guiding member.
(5)

The light detecting device according to any one of (1) to (4), in which the second light-guiding member is provided to be adjacent to the first light-guiding member.
(6)

The light detecting device according to any one of (1) to (5), in which the first photoelectric conversion element photoelectrically converts light incident via the first filter and the second light-guiding member.
(7)

The light detecting device according to any one of (1) to (6), further including a lens on which light is incident, the lens being provided above the first filter, in which
the first photoelectric conversion element photoelectrically converts light incident via the lens, the first filter, and the second light-guiding member.
(8)

The light detecting device according to (7), in which a center position of the lens differs from a center position of the first filter, in a direction orthogonal to a direction of stacking the lens and the first filter.
(9)

The light detecting device according to any one of (1) to (8), in which a width of the second light-guiding member is larger than a width of the first light-guiding member, in a direction orthogonal to a direction of stacking the first filter and the first photoelectric conversion element.
(10)

The light detecting device according to any one of (1) to (9), in which the first pixel includes the first photoelectric conversion element and a second photoelectric conversion element provided next to the first photoelectric conversion element.
(11)

The light detecting device according to any one of (1) to (10), in which the first pixel includes a pixel usable for detection of a phase difference.
(12)

The light detecting device according to any one of (1) to (11), in which the first filter includes a filter that transmits green light.
(13)

The light detecting device according to any one of (1) to (12), including a pixel array provided with a plurality of pixels including the first pixel and the second pixel,
the pixel array is provided with a plurality of the second light-guiding members having different sizes depending on a distance from a center of the pixel array.
(14)

The light detecting device according to any one of (1) to (13), in which
the first pixel and the second pixel each include the second light-guiding member, and
the second light-guiding member of the first pixel and the second light-guiding member of the second pixel have different sizes.
(15)

The light detecting device according to any one of (1) to (14), in which
the first pixel and the second pixel each include the second light-guiding member, and
the second light-guiding member of the first pixel and the second light-guiding member of the second pixel have different refractive indexes.
(16)

The light detecting device according to any one of (1) to (15), in which
the first filter includes the filter that transmits green light, and
the second filter includes a filter that transmits red light or a filter that transmits blue light.
(17)

The light detecting device according to any one of (1) to (16), in which the second light-guiding member is configured using a dielectric material having a refractive index higher than the refractive index of the first light-guiding member.
(18)

The light detecting device according to any one of (1) to (17), in which the first light-guiding member is configured using an air gap.
(19)

An electronic apparatus including:
an optical system; and
a light detecting device that receives light transmitted through the optical system,
the light detecting device including
   a first pixel and a second pixel each including a first photoelectric conversion element that photoelectrically converts light,
   a first filter provided in a manner corresponding to the first pixel,
   a second filter provided in a manner corresponding to the second pixel,
   a first light-guiding member provided between the first filter and the second filter, and
   a second light-guiding member provided around the first light-guiding member, the second light-guiding member having a refractive index higher than a refractive index of the first light-guiding member.

The present application claims the benefit of Japanese Priority Patent Application JP2023-094208 filed with the Japan Patent Office on Jun. 7, 2023, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light detecting device comprising:
a first pixel and a second pixel each including a first photoelectric conversion element that photoelectrically converts light;
a first filter provided in a manner corresponding to the first pixel;
a second filter provided in a manner corresponding to the second pixel;
a first light-guiding member provided between the first filter and the second filter; and
a second light-guiding member provided around the first light-guiding member, the second light-guiding member having a refractive index higher than a refractive index of the first light-guiding member.

2. The light detecting device according to claim 1, wherein at least a portion of the second light-guiding member is provided on a side of the first filter opposite to a side on which light is incident.

3. The light detecting device according to claim 1, wherein at least a portion of the second light-guiding member is provided between the first light-guiding member and the first photoelectric conversion element.

4. The light detecting device according to claim 1, wherein at least a portion of the second light-guiding member is provided in the first light-guiding member.

5. The light detecting device according to claim 1, wherein the second light-guiding member is provided to be adjacent to the first light-guiding member.

6. The light detecting device according to claim 1, wherein the first photoelectric conversion element photoelectrically converts light incident via the first filter and the second light-guiding member.

7. The light detecting device according to claim 1, further comprising a lens on which light is incident, the lens being provided above the first filter, wherein
the first photoelectric conversion element photoelectrically converts light incident via the lens, the first filter, and the second light-guiding member.

8. The light detecting device according to claim 7, wherein a center position of the lens differs from a center position of the first filter, in a direction orthogonal to a direction of stacking the lens and the first filter.

9. The light detecting device according to claim 1, wherein a width of the second light-guiding member is larger than a width of the first light-guiding member, in a direction orthogonal to a direction of stacking the first filter and the first photoelectric conversion element.

10. The light detecting device according to claim 1, wherein the first pixel includes the first photoelectric conversion element and a second photoelectric conversion element provided next to the first photoelectric conversion element.

11. The light detecting device according to claim 1, wherein the first pixel comprises a pixel usable for detection of a phase difference.

12. The light detecting device according to claim 1, wherein the first filter comprises a filter that transmits green light.

13. The light detecting device according to claim 1, comprising a pixel array provided with a plurality of pixels including the first pixel and the second pixel,
the pixel array is provided with a plurality of the second light-guiding members having different sizes depending on a distance from a center of the pixel array.

14. The light detecting device according to claim 1, wherein
the first pixel and the second pixel each include the second light-guiding member, and
the second light-guiding member of the first pixel and the second light-guiding member of the second pixel have different sizes.

15. The light detecting device according to claim 1, wherein
the first pixel and the second pixel each include the second light-guiding member, and
the second light-guiding member of the first pixel and the second light-guiding member of the second pixel have different refractive indexes.

16. The light detecting device according to claim 1, wherein
the first filter comprises a filter that transmits green light, and
the second filter comprises a filter that transmits red light or a filter that transmits blue light.

17. The light detecting device according to claim 1, wherein the second light-guiding member is configured using a dielectric material having a refractive index higher than the refractive index of the first light-guiding member.

18. The light detecting device according to claim 1, wherein the first light-guiding member is configured using an air gap.

19. An electronic apparatus comprising:
an optical system; and
a light detecting device that receives light transmitted through the optical system,
the light detecting device including
a first pixel and a second pixel each including a first photoelectric conversion element that photoelectrically converts light,
a first filter provided in a manner corresponding to the first pixel,
a second filter provided in a manner corresponding to the second pixel,
a first light-guiding member provided between the first filter and the second filter, and
a second light-guiding member provided around the first light-guiding member, the second light-guiding member having a refractive index higher than a refractive index of the first light-guiding member.
